(19) United States
(12) Patent Application Publication
(10) Pub. No.: US 2023/0069399 A1
(43) Pub. Date: Mar. 2, 2023

(54) MICROELECTRONIC DEVICES HAVING TRANSITION AREAS INCLUDING UPPER DUMMY PILLARS SPACED FROM SOURCE/DRAIN CONTACTS, AND RELATED METHODS AND SYSTEMS

(71) Applicant: Micron Technology, Inc., Boise, ID (US)

(72) Inventors: Kailing Shih, Singapore (SG); Dong Wang, Singapore (SG); Pei Qiong Cheung, Singapore (SG)

(21) Appl. No.: 17/446,370

(22) Filed: Aug. 30, 2021

(51) Int. Cl. H01L 23/00; H01L 27/11556; H01L 27/11582

(52) U.S. Cl. CPC H01L 23/562; H01L 27/11556; H01L 27/11582

(57) ABSTRACT

A microelectronic device includes a stack structure comprising a vertically alternating sequence of insulative structures and conductive structures arranged in tiers and the tiers arranged in decks. At least one live pillar, comprising a channel material, extends through the decks to a source/drain region. At least one source/drain contact also extends through the decks. In a transition area horizontally between the live pillar(s) and the source/drain contact(s), at least one dummy pillar extends through at least one of the decks. The dummy pillar(s) are separated from the source/drain region by at least one of the tiers of a lower of the decks. The dummy pillar(s) are also spaced from the source/drain contact(s). Additional microelectronic devices are also disclosed, as are related methods and electronic systems.

### TECHNICAL FIELD

Embodiments of the disclosure relate to the field of microelectronic device design and fabrication. More particularly, the disclosure relates to microelectronic devices (e.g., memory devices, such as 3D NAND memory devices) having tiered stack structures with multiple decks and that include, only or primarily in a transition area of an upper deck, dummy pillars horizontally adjacent to and spaced from conductive source/drain contacts that extend through the decks. The disclosure also relates to methods for forming such devices and to systems incorporating such devices.

### BACKGROUND

Memory devices provide data storage for electronic systems. A Flash memory device is one of various memory device types and has numerous uses in modern computers and other electrical devices. A conventional Flash memory device may include a memory array that has a large number of charge storage devices (e.g., memory cells, such as non-volatile memory cells) arranged in rows and columns. In a NAND architecture type of Flash memory, memory cells arranged in a column are coupled in series, and a first memory cell of the column is coupled to a data line (e.g., a bit line). In a “three-dimensional NAND” memory device (which may also be referred to herein as a “3D NAND” memory device), a type of vertical memory device, not only are the memory cells arranged in row and column fashion in a horizontal array, but tiers of the horizontal arrays are stacked over one another (e.g., as vertical strings of memory cells) to provide a “three-dimensional array” of the memory cells. The stack of tiers vertically alternate conductive materials with insulating (e.g., dielectric) materials. The conductive materials function as control gates for, e.g., access lines (e.g., word lines) of the memory cells. Vertical structures (e.g., pillars comprising channel structures and tunneling structures) extend along the vertical string of memory cells. A drain end of a string is adjacent one of the top and bottom of the vertical structure (e.g., pillar), while a source end of the string is adjacent the other of the top and bottom of the pillar. The drain end is operably connected to a bit line, while the source end is operably connected to a source line. A 3D NAND memory device also includes electrical connections between, various conductive structures of the device (e.g., between the pillars and the source/drain contacts) so that the memory cells of the vertical strings can be selected for writing, reading, and erasing operations.

A continued goal in the microelectronic device fabrication industry is to design and fabricate device structures with reliable formation of features. However, conventional materials and structures of microelectronic device designs tend to exhibit uneven material stresses and strains that can cause structural deformation (e.g., bending) of features. Structural deformations may lead to misalignments between features intended to be aligned, electrical shorting between features intended to be electrically isolated, removal of material from features not intended to be subject to the material removal, formation of some features with smaller-than-intended dimensions and/or other features with greater-than-intended dimensions, and other material or structural defects that may negatively impact device functionality or performance parameters. Accordingly, designing and fabricating microelectronic devices, such as 3D NAND memory devices, continues to present challenges.

### BRIEF DESCRIPTION OF THE DRAWINGS

FIG. 1 is a cross-sectional, elevational, schematic illustration of a microelectronic device structure, wherein dummy pillars are included in an upper deck of a tiered stack structure and are horizontally interposed, in a transition area, between live pillars and source/drain contacts, in accordance with embodiments of the disclosure.

FIG. 2A is an enlarged view of box 144 of FIG. 1, in accordance with embodiments of the disclosure in which dummy pillars extend partially below the upper deck of the microelectronic device structure of FIG. 1.

FIG. 2B is an enlarged view of box 144 of FIG. 1, in accordance with embodiments of the disclosure in which dummy pillars do not extend below the upper deck of the microelectronic device structure of FIG. 1 and with a channel material extending through outer cell materials of the dummy pillars.

FIG. 2C is an enlarged view of box 144 of FIG. 1, in accordance with embodiments of the disclosure in which dummy pillars do not extend below the upper deck of the microelectronic device structure of FIG. 1 and with a channel material not extending through outer cell materials of the dummy pillars.

FIG. 3 is a top plan, schematic illustration of the microelectronic device structure of FIG. 1, wherein the view of FIG. 1 is taken along section line A-A of FIG. 3, in accordance with embodiments of the disclosure.

FIG. 4A is a top plan, schematic illustration of a microelectronic device that may include the microelectronic device structures of any or all of FIG. 1 through FIG. 3, in accordance with embodiments of the disclosure.

FIG. 4B is a top plan, schematic illustration of a periphery area of the microelectronic device of FIG. 4A, in accordance with embodiments of the disclosure.

FIG. 4C is a top plan, schematic illustration of a plane separation area of the microelectronic device of FIG. 4A, in accordance with embodiments of the disclosure.

FIG. 4D is a top plan, schematic illustration of a read-only memory (ROM) area of the microelectronic device of FIG. 4A, in accordance with embodiments of the disclosure.

FIG. 4E is a top plan, schematic illustration of a bit line exit area of the microelectronic device of FIG. 4A, in accordance with embodiments of the disclosure.

FIG. 5A and FIG. 5B are each a cross-sectional, elevational, schematic illustration of a memory cell, in accordance with embodiments of the disclosure, wherein the illustrated area may corresponds to, e.g., each of boxes 154 of FIG. 1.

FIG. 6 through FIG. 17 are cross-sectional, elevational, schematic illustrations of various stages of processing to fabricate the microelectronic device structures of FIG. 1 through FIG. 4E, in accordance with embodiments of the disclosure, wherein figures designated with a number and the letter “B” (FIG. 9B, FIG. 10B, FIG. 11B, FIG. 12B, and FIG. 16B) are each, respectively, an enlarged view of box 144 of the figure with the same number and the letter “A” (FIG. 9A, FIG. 10A, FIG. 11A, FIG. 12A, and FIG. 16A, respectively).

FIG. 18 is a partial, cutaway, perspective, schematic illustration of a microelectronic device, in accordance with embodiments of the disclosure.

FIG. 19 is a block diagram of an electronic system, in accordance with embodiments of the disclosure.

FIG. 20 is a block diagram of a processor-based system, in accordance with embodiments of the disclosure.

### DETAILED DESCRIPTION

Structures (e.g., microelectronic device structures), apparatus (e.g., microelectronic devices), and systems (e.g., electronic systems), in accordance with embodiments of the disclosure, include a multideck stack of vertically alternating conductive structures and insulative structures arranged in tiers through which pillars vertically extend. In pillar array areas, blocks of “live” pillars extend through the multiple decks of the stack. In transition areas, horizontally between source/drain contacts and the blocks with the live pillars, “dummy” pillars extend through only or primarily an upper deck of the stack. The dummy pillars may inhibit block bending, which may facilitate reliable fabrication of features of the microelectronic device(s) that include these upper-deck dummy pillars (which may be otherwise referred to herein as “upper dummy pillars”).

As used herein, the terms “live” and “active,” when used in reference to a pillar, contact, or other semiconductive or conductive structure, means and includes a pillar, contact, or other semiconductive or conductive structure configured to be functionally involved in at least one operation of features of the microelectronic device, such as charge storage, electrical communication to other component(s), and/or writing, reading, and/or erasing operations of the device. In contrast, a “dummy,” “non-active,” “non-live,” or “support” pillar, contact, or other structure means and refers to a pillar, contact, or other structure not functionally involved in at least one storage or electrical operation of features of the microelectronic device.

As used herein, a feature referred to with the adjective “source/drain” means and refers to the feature being configured for association with either or both the source region and the drain region of the device that includes the “source/drain” feature. A “source region” may be otherwise configured as a “drain region” and vice versa without departing from the scope of the disclosure.

As used herein, the terms “opening,” “trench,” “slit,” “recess,” and “void” mean and include a volume extending through or into at least one structure or at least one material, leaving a gap in that at least one structure or at least one material, or a volume extending between structures or materials, leaving a gap between the structures or materials. Unless otherwise described, an “opening,” “trench,” “slit,” and/or “recess” is not necessarily empty of material. That is, an “opening,” “trench,” “slit,” or “recess” is not necessarily void space. An “opening,” “trench,” “slit,” or “recess” formed in or between structures or materials may comprise structure(s) or material(s) other than that in or between which the opening is formed. And, structure(s) or material(s) “exposed” within an opening, trench, slit, or recess is/are not necessarily in contact with an atmosphere or non-solid environment. Structure(s) or material(s) “exposed” within an opening, trench, slit, or recess may be adjacent or in contact with other structure(s) or material(s) that is/are disposed within the opening, trench, slit, or recess. In contrast, unless otherwise described, a “void” may be substantially or wholly empty of material. A “void” formed in or between structures or materials may not comprise structure(s) or material(s) other than that in or between which the “void” is formed. And, structure(s) or material(s) “exposed” within a “void” may be in contact with an atmosphere or non-solid environment.

As used herein, the terms “trench” and “slit” mean and include an elongate opening, while the terms “opening,” “recess,” and “void” may include one or more of an elongate opening, an elongate recess, an elongate void, a non-elongate opening, a non-elongate recess, or a non-elongate void.

As used herein, the term “elongate” means and includes a geometric shape including a dimension (e.g., a length, as defined below) in a first horizontal direction (e.g., a longitudinal direction, as defined below) that is greater than an additional dimension (e.g., a width, as defined below) in a second horizontal direction (e.g., a lateral direction, as defined below) orthogonal to the first horizontal direction.

As used herein, the terms “substrate” and “base structure” mean and include a base material or other construction upon which or in which components, such as circuitry components and/or doped regions for source/drain region(s), are formed. The substrate or base structure may be or include a semiconductor substrate, a base semiconductor material on a supporting structure, a metal electrode, or a semiconductor substrate having one or more materials, structures, or regions formed thereon. The substrate may be or include a conventional silicon substrate or other bulk substrate including a semiconductive material. As used herein, the term “bulk substrate” means and includes not only silicon wafers, but also silicon-on-insulator (“SOT”) substrates, such as silicon-on-sapphire (“SOS”) substrates or silicon-on-glass (“SOG”) substrates, epitaxial layers of silicon on a base semiconductor foundation, or other semiconductor or optoelectronic materials, such as silicon-germanium (Si₁₋ₓGeₓ, where x is, for example, a mole fraction between 0.2 and 0.8), germanium (Ge), gallium arsenide (GaAs), gallium nitride (GaN), or indium phosphide (InP), among others. Furthermore, when reference is made to a “substrate” or “base structure” in the following description, previous process stages may have been utilized to form materials, structures, or junctions in the base semiconductor structure, base structure, or other foundation.

As used herein, the terms “insulative” and “insulating,” when used in reference to a material or structure, means and includes a material or structure that is electrically insulating. An “insulative” material or structure may be formed of and include one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric carboxynitride material (e.g., a silicon carboxynitride (SiOₓC_{z}N_{y})), and/or air. Formulae including one or more of “x,” “y,” and/or “z” herein (e.g., SiOₓ, AlOₓ, HfOₓ, NbO—ₓ, TiOₓ, SiN_{y}, SiOₓN_{y}, SiOₓC_{z}N_{y}) represent a material that contains an average ratio of “x” atoms of one element, “y” atoms of another element, and/or “z” atoms of an additional element (if any), respectively, for every one atom of another element (e.g., Si, Al, Hf, Nb, Ti). As the formulae are representative of relative atomic ratios and not strict chemical structure, an insulative material or insulative structure may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, the term “sacrificial,” when used in reference to a material or structure, means and includes a material or structure that is formed during a fabrication process but which is removed (e.g., substantially removed) prior to completion of the fabrication process.

As used herein, the term “horizontal” means and includes a direction that is parallel to a primary surface of the substrate on which the referenced material or structure is located. The “width” and “length” of a respective material or structure may be defined as dimensions in a horizontal plane. With reference to the figures, the “horizontal” direction may be perpendicular to an indicated “Z” axis, may be parallel to an indicated “X” axis, and may be parallel to an indicated “Y” axis.

As used herein, the term “lateral” means and includes a direction in a horizontal plane parallel to a primary surface of the substrate on which a referenced material or structure is located and substantially perpendicular to a “longitudinal” direction. The “width” of a respective material or structure may be defined as a dimension in the lateral direction of the horizontal plane. With reference to the figures, the “lateral” direction may be parallel to an indicated “X” axis, may be perpendicular to an indicated “Y” axis, and may be perpendicular to an indicated “Z” axis.

As used herein, the term “longitudinal” means and includes a direction in a horizontal plane parallel to a primary surface of the substrate on which a referenced material or structure is located, and substantially perpendicular to a “lateral” direction. The “length” of a respective material or structure may be defined as a dimension in the longitudinal direction of the horizontal plane. With reference to the figures, the “longitudinal” direction may be parallel to an indicated “Y” axis, may be perpendicular to an indicated “X” axis, and may be perpendicular to an indicated “Z” axis.

As used herein, the term “vertical” means and includes a direction that is perpendicular to a primary surface of the substrate on which a referenced material or structure is located. The “height” of a respective material or structure may be defined as a dimension in a vertical plane. With reference to the figures, the “vertical” direction may be parallel to an indicated “Z” axis, may be perpendicular to an indicated “X” axis, and may be perpendicular to an indicated “Y” axis.

As used herein, the term “width” means and includes a dimension, along an indicated “X” axis in a horizontal plane (e.g., at a certain elevation, if identified), defining a maximum distance, along such “X” axis in the horizontal plane, of the material or structure in question. For example, a “width” of a structure that is at least partially hollow, or that is at least partially filled with one or more other material(s), is the horizontal dimension between outermost edges or sidewalls of the structure, such as an outer “X”-axis diameter for a hollow or filled, cylindrical structure.

As used herein, the term “length” means and includes a dimension, along an indicated “Y” axis in a horizontal plane (e.g., at a certain elevation, if identified), defining a maximum distance, along such “Y” axis in the horizontal plane, of the material or structure in question. For example, a “length” of a structure that is at least partially hollow, or that is at least partially filled with one or more other material(s), is the horizontal dimension between outermost edges or sidewalls of the structure, such as an outer “Y”-axis diameter for a hollow or filled, cylindrical structure.

As used herein, the terms “thickness” or “thinness” are spatially relative terms that mean and include a dimension in a straight-line direction that is normal to the closest surface of an immediately adjacent material or structure that is of a different composition or that is otherwise distinguishable from the material or structure whose thickness, thinness, or height is discussed.

As used herein, the term “between” is a spatially relative term used to describe the relative disposition of one material, structure, or sub-structure relative to at least two other materials, structures, or sub-structures. The term “between” may encompass both a disposition of one material, structure, or sub-structure directly adjacent the other materials, structures, or sub-structures and a disposition of one material, structure, or sub-structure indirectly adjacent to the other materials, structures, or sub-structures.

As used herein, the term “proximate” is a spatially relative term used to describe disposition of one material, structure, or sub-structure near to another material, structure, or sub-structure. The term “proximate” includes dispositions of indirectly adjacent to, directly adjacent to, and internal to.

As used herein, the term “neighboring,” when referring to a material or structure, is a spatially relative term that means and refers to a next, most proximate material or structure of an identified composition or characteristic. Materials or structures of other compositions or characteristics than the identified composition or characteristic may be disposed between one material or structure and its “neighboring” material or structure of the identified composition or characteristic. For example, a structure of material X “neighboring” a structure of material Y is the first material X structure, e.g., of multiple material X structures, that is most proximate to the particular structure of material Y. The “neighboring” material or structure may be directly adjacent or indirectly adjacent the structure or material of the identified composition or characteristic.

As used herein, the term “consistent”—when referring to a parameter, property, or condition of one structure, material, feature, or portion thereof in comparison to the parameter, property, or condition of another such structure, material, feature, or portion of such same aforementioned structure, material, or feature—is a relative term that means and includes the parameter, property, or condition of the two such structures, materials, features, or portions being equal, substantially equal, or about equal, at least in terms of respective dispositions of such structures, materials, features, or portions. For example, a structure with a “consistent” thickness may have the same thickness of material at elevation Y1 of such structure as at elevation Y2 of such structure. As another example, two structures with “consistent” thicknesses may define the same structure thickness at X lateral distance from another feature, despite the two structures being at different elevations along such other feature.

As used herein, the terms “about” and “approximately,” when either is used in reference to a numerical value for a particular parameter, are inclusive of the numerical value and a degree of variance from the numerical value that one of ordinary skill in the art would understand is within acceptable tolerances for the particular parameter. For example, “about” or “approximately,” in reference to a numerical value, may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “substantially,” when referring to a parameter, property, or condition, means and includes the parameter, property, or condition being equal to or within a degree of variance from a given value such that one of ordinary skill in the art would understand such given value to be acceptably met, such as within acceptable manufacturing tolerances. By way of example, depending on the particular parameter, property, or condition that is substantially met, the parameter, property, or condition may be “substantially” a given value when the value is at least 90.0 percent met, at least 95.0 percent met, at least 99.0 percent met, or even at least 99.9 percent met.

As used herein, the terms “on” or “over,” when referring to an element as being “on” or “over” another element, are spatially relative terms that mean and include the element being directly on top of, adjacent to (e.g., laterally adjacent to, horizontally adjacent to, longitudinally adjacent to, vertically adjacent to), underneath, or in direct contact with the other element. It also includes the element being indirectly on top of, adjacent to (e.g., laterally adjacent to, horizontally adjacent to, longitudinally adjacent to, vertically adjacent to), underneath, or near the other element, with other elements present therebetween. In contrast, when an element is referred to as being “directly on” or “directly adjacent to” another element, there are no intervening elements present.

As used herein, other spatially relative terms, such as “below,” “lower,” “bottom,” “above,” “upper,” “top,” and the like, may be used for ease of description to describe one element's or feature's relationship to another element(s) or feature(s) as illustrated in the figures. Unless otherwise specified, any spatially relative terms used in this disclosure are intended to encompass different orientations of the materials in addition to the orientation as depicted in the figures. For example, if materials in the figures are inverted, elements described as “below” or “under” or “on bottom of” other elements or features would then be oriented “above” or “on top of” the other elements or features. Thus, the term “below” may encompass both an orientation of above and below, depending on the context in which the term is used, which will be evident to one of ordinary skill in the art. The materials may be otherwise oriented (rotated ninety degrees, inverted, etc.) and the spatially relative descriptors used herein interpreted accordingly.

As used herein, the terms “level” and “elevation” are spatially relative terms used to describe one material's or feature's relationship to another material(s) or feature(s) as illustrated in the figures, using—as a reference point—the lowest illustrated surface of the structure that includes the materials or features. As used herein, a “level” and an “elevation” are each defined by a horizontal plane parallel to a primary surface of the substrate or base structure on or in which the structure (that includes the materials or features) is formed. “Lower levels” and “lower elevations” are relatively nearer to the bottom-most illustrated surface of the respective structure, while “higher levels” and “higher elevations” are relatively further from the bottom-most illustrated surface of the respective structure. Unless otherwise specified, any spatially relative terms used in this disclosure are intended to encompass different orientations of the materials in addition to the orientation as depicted in the figures. For example, the materials in the figures may be inverted, rotated, etc., with the “upper” levels and elevations then illustrated proximate the bottom of the page and the “lower” levels and elevations then illustrated proximate the top of the page.

As used herein, the term “depth” is a spatially relative term used to describe one material's or feature's relationship to another material(s) or feature(s) as illustrated in the figures, using—as a reference point—the highest illustrated surface of the structure that includes the materials or features. As used herein, a “depth” is defined by a horizontal plane parallel to the highest illustrated surface of the structure that includes the materials or features.

Unless otherwise specified, any spatially relative terms used in this disclosure are intended to encompass different orientations of the materials in addition to the orientation as depicted in the figures. For example, the materials in the figures may be inverted, rotated, etc., with the “upper” levels and elevations then illustrated proximate the bottom of the page, the “lower” levels and elevations then illustrated proximate the top of the page, and the greatest “depths” extending a greatest vertical distance upward.

As used herein, the terms “comprising,” “including,” “having,” and grammatical equivalents thereof are inclusive, open-ended terms that do not exclude additional, unrecited elements or method steps. These terms also include more restrictive terms “consisting of” and “consisting essentially of” and grammatical equivalents thereof. Therefore, a structure described as “comprising,” “including,” and/or “having” a material may be a structure that, in some embodiments, includes additional material(s) as well and/or a structure that, in some embodiments, does not include any other material(s). Likewise, a composition (e.g., gas) described as “comprising,” “including,” and/or “having” a species may be a composition that, in some embodiments, includes additional species as well and/or a composition that, in some embodiments, does not include any other species.

As used herein, the term “may” with respect to a material, structure, feature, or method act indicates that such is contemplated for use in implementation of an embodiment of the disclosure and such term is used in preference to the more restrictive term “is” so as to avoid any implication that other, compatible materials, structures, features, and methods usable in combination therewith should or must be excluded.

As used herein, “and/or” means and includes any and all combinations of one or more of the associated listed items.

As used herein, the singular forms “a,” “an,” and “the” are intended to include the plural forms as well, unless the context clearly indicates otherwise.

As used herein, a “(s)” at the end of a term means and includes the singular form of the term and/or the plural form of the term, unless the context clearly indicates otherwise.

As used herein, the terms “configured” and “configuration” mean and refer to a size, shape, material composition, orientation, and arrangement of a referenced material, structure, assembly, or apparatus so as to facilitate a referenced operation or property of the referenced material, structure, assembly, or apparatus in a predetermined way.

The illustrations presented herein are not meant to be actual views of any particular material, structure, sub-structure, region, sub-region, device, system, or stage of fabrication, but are merely idealized representations that are employed to describe embodiments of the disclosure.

Embodiments are described herein with reference to cross-sectional illustrations that are schematic illustrations. Accordingly, variations from the shapes of the illustrations as a result, for example, of manufacturing techniques and/or tolerances, are to be expected. Thus, embodiments described herein are not to be construed as limited to the particular shapes or structures as illustrated but may include deviations in shapes that result, for example, from manufacturing techniques. For example, a structure illustrated or described as box-shaped may have rough and/or nonlinear features. Moreover, sharp angles that are illustrated may be rounded. Thus, the materials, features, and structures illustrated in the figures are schematic in nature and their shapes are not intended to illustrate the precise shape of a material, feature, or structure and do not limit the scope of the present claims.

The following description provides specific details, such as material types and processing conditions, to provide a thorough description of embodiments of the disclosed apparatus (e.g., devices, systems) and methods. However, a person of ordinary skill in the art will understand that the embodiments of the apparatus and methods may be practiced without employing these specific details. Indeed, the embodiments of the apparatus and methods may be practiced in conjunction with conventional semiconductor fabrication techniques employed in the industry.

The fabrication processes described herein do not form a complete process flow for processing apparatus (e.g., devices, systems) or the structures thereof. The remainder of the process flow is known to those of ordinary skill in the art. Accordingly, only the methods and structures necessary to understand embodiments of the present apparatus (e.g., devices, systems) and methods are described herein.

Unless the context indicates otherwise, the materials described herein may be formed by any suitable technique including, but not limited to, spin coating, blanket coating, chemical vapor deposition (“CVD”), atomic layer deposition (“ALD”), plasma enhanced ALD, physical vapor deposition (“PVD”) (e.g., sputtering), or epitaxial growth. Depending on the specific material to be formed, the technique for depositing or growing the material may be selected by a person of ordinary skill in the art.

Unless the context indicates otherwise, the removal of materials described herein may be accomplished by any suitable technique including, but not limited to, etching (e.g., dry etching, wet etching, vapor etching), ion milling, abrasive planarization, or other known methods.

In referring to the drawings, like numerals refer to like components throughout. The drawings are not necessarily drawn to scale.

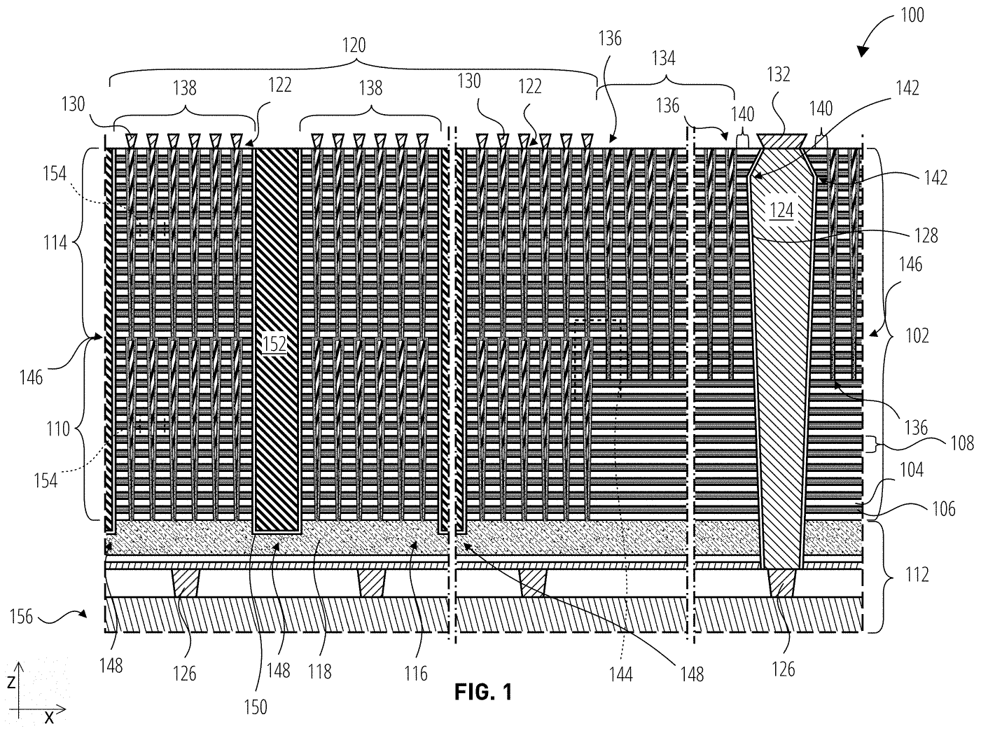

With reference to FIG. 1, illustrated, in elevational cross-sectional view, is a microelectronic device structure 100 that includes a stack structure 102 including vertically alternating (e.g., vertically interleaved) insulative structures 104 and conductive structures 106 arranged in tiers 108. Each of the tiers 108 may individually include at least one of the insulative structures 104 and at least one of the conductive structures 106 vertically neighboring the at least one of the insulative structures 104. The stack structure 102 includes multiple decks of the tiers 108, such as a lower deck 110 (e.g., above a base structure 112) and an upper deck 114 (e.g., about the lower deck 110).

In some embodiments, one or more additional decks (e.g., “intermediate” deck(s)) may be included between the lower deck 110 and the upper deck 114. Accordingly, while FIG. 1 illustrates only two decks (e.g., the upper deck 114 and the lower deck 110). For example, a microelectronic device structure in accordance with embodiments of the disclosure may include three or more decks (e.g., the lower deck 110, one or more intermediate decks, and the upper deck 114). The intermediate deck(s) may have a structure matching that illustrated for the lower deck 110, a structure matching that illustrated for the upper deck 114, or a different structure.

Though FIG. 1 illustrates thirteen (13) tiers 108 (e.g., thirteen (13) conductive structures 106) in each deck, the disclosure is not so limiting. In some embodiments, a number (e.g., quantity) of the tiers 108 of the stack structure 102—and therefore the number (e.g., quantity) of conductive structures 106 in the stack structure 102—is within a range of from thirty-two of the tiers 108 (and of the conductive structures 106) to three-hundred, or more, of the tiers 108 (and of the conductive structures 106). In some embodiments, the stack structure 102 includes one-hundred twenty-eight of the tiers 108 (and of the conductive structures 106). However, the disclosure is not so limited, and the stack structure 102 may include a different number of the tiers 108 (and of the conductive structures 106). Each deck (e.g., each of the lower deck 110, the upper deck 114, and intermediate deck(s), if any) may include the same or a different number of tiers 108 as one another.

In the stack structure 102, the insulative structures 104 may be formed of and include at least one insulative material, such as a dielectric oxide material (e.g., silicon dioxide). In this and other embodiments described herein, the insulative material of the insulative structures 104 may be substantially the same as or different than other insulative material(s) of the microelectronic device structure 100.

The conductive structures 106 of the stack structure 102 may be formed of and include one or more conductive materials, such as one or more of: at least one metal (e.g., one or more of tungsten, titanium, nickel, platinum, rhodium, ruthenium, iridium, aluminum, copper, molybdenum, silver, gold), at least one alloy (e.g., an alloy of one or more of the aforementioned metals), at least one metal-containing material that includes one or more of the aforementioned metals (e.g., metal nitrides, metal silicides, metal carbides, metal oxides, such as a material including one or more of titanium nitride (TiN), tantalum nitride (TaN), tungsten nitride (WN), titanium aluminum nitride (TiAlN), iridium oxide (IrOₓ), ruthenium oxide (RuOₓ), alloys thereof), at least one conductively-doped semiconductor material (e.g., conductively-doped silicon, conductively-doped germanium, conductively-doped silicon germanium), polysilicon, and at least one other material exhibiting electrical conductivity. In some embodiments, the conductive structures 106 include at least one of the aforementioned conductive materials, along with at least one additional conductive material formed as a liner.

In some embodiments, one or more of the conductive structures 106 neighboring the source/drain region 116 of the doped material 118 may be configured as gate-induced drain leakage (“GIDL”) region(s), such as a source-gate select device (e.g., a SGS device). In some such embodiments, one or more conductive structures 106 atop the stack structure 102 may also be configured as GIDL region(s), such as a drain-gate select device (e.g., a SGD device).

Pillars that include channel material extend fully or partially through the stack structure 102. In live pillar array portions 120 of the microelectronic device structure 100, the pillars are structured or otherwise configured as live pillars 122 and extend through all decks (e.g., the upper deck 114 and the lower deck 110) of the stack structure 102 to communicate with a source/drain region 116 below the stack structure 102.

The base structure 112 may be formed of and include, for example, one or more semiconductor materials (e.g., polycrystalline silicon (polysilicon)). Adjacent the stack structure 102, the semiconductor material may be doped (e.g., forming doped material 118) to provide the source/drain region 116 adjacent a lower end of the live pillars 122. The doped material 118 may be formed of and include, for example, a semiconductor material (e.g., polysilicon) doped with one or more P-type conductivity chemical species (e.g., one or more of boron, aluminum, and gallium) or one or more N-type conductivity chemical species (e.g., one or more of arsenic, phosphorous, and antimony).

Horizontally spaced from the live pillar array portion 120, source/drain contacts 124 extend through the decks (e.g., the upper deck 114, the lower deck 110) of the stack structure 102 and through the doped material 118 of the source/drain region 116 to land on conductive landing structures 126 in the base structure 112. One or more dielectric liners 128 may horizontally surround conductive material of the source/drain contact 124 and space the source/drain contact 124 from the materials of the stack structure 102.

The source/drain contacts 124 may be formed of and comprise one or more electrically conductive materials, such as any one or more of the conductive materials discussed above with regard to the conductive structures 106. In some embodiments, the source/drain contacts 124 are formed of and include conductive material exhibiting substantially tensile stress (e.g., tungsten, titanium). For example, the source/drain contacts 124 may comprise primarily tungsten and may also comprise a titanium liner around the tungsten, and both the tungsten and the titanium of the source/drain contacts 124 may exhibit substantially tensile stress.

The dielectric liner 128 may comprise any one or more of the insulative materials described above with regard to the insulative structures 104. In some embodiments, the dielectric liner 128 may be formed of and include dielectric oxide material (e.g., silicon oxide, such as silicon dioxide (SiO₂)).

The live pillars 122 and the source/drain contacts 124 are configured to be in electrical communication with one another via, for example, conductive plugs 130 directly on the live pillars 122 (e.g., directly on upper ends of the live pillars 122) and additional conductive structures 132 directly on the source/drain contacts 124. Additional conductive routing lines (not illustrated) may be in physical contact with respective conductive plugs 130 and additional conductive structures 132 to electrically connect respective live pillars 122 and source/drain contacts 124. Below the stack structure 102, the conductive landing structures 126 electrically connect the source/drain contacts 124 (and therefore also the live pillars 122) to other electrical components of the microelectronic device structure 100, such as other circuitry features. In some embodiments, the base structure 112 includes features configured as complementary metal-oxide-semiconductor (CMOS) circuitry, such that the microelectronic device structure 100 is characterizable as having a so-called “CMOS under array” (“CuA”) region in the base structure 112.

In areas of the microelectronic device structure 100 horizontally interposed between the source/drain contacts 124 and the live pillar array portion 120—which areas are herein referred to as “transition areas 134”—additional pillars are included but are configured as non-functional “dummy” pillars (dummy pillars 136). As discussed further below, the presence of the dummy pillars 136 between the live pillar array portion 120 and the source/drain contacts 124 may inhibit structural deformations in, e.g., the live pillar array portion 120 that may otherwise result in feature misalignments (e.g., between the conductive plugs 130 and the live pillars 122) or other challenges during fabrication.

For example, the materials of the dummy pillars 136 may exhibit substantially compressive stress while the materials of the source/drain contacts 124 may exhibit substantially tensile stress. The compressive stress exhibited by the dummy pillars 136 may negate or lessen the effects of the tensile stress exhibited by the source/drain contacts 124 so that the formation of the source/drain contacts 124 may not cause structural deformation of the live pillars 122 or the blocks 138. By avoiding such pillar bending and block bending, the live pillars 122 and the blocks 138 may be more reliably formed, as discussed further below.

The dummy pillars 136 may include substantially the same materials and sub-structures as the live pillars 122, as discussed further below, but may not be in physical contact or other electrical communication with other electrically-active features of the microelectronic device structure 100, such as the conductive plugs 130, the source/drain region 116, the source/drain contacts 124, the additional conductive structures 132, and the conductive landing structures 126.

In some embodiments, the horizontal distance spacing one dummy pillar 136 from a neighboring dummy pillar 136 is substantially the same as the horizontal distance spacing one live pillar 122 from a neighboring live pillar 122 in the live pillar array portions 120. In these or other embodiments, the pitch of the live pillars 122 (e.g., the center-to-center distance of neighboring live pillars 122) may be substantially the same as the pitch of the dummy pillars 136 (e.g., the center-to-center distance of neighboring dummy pillars 136). In other embodiments, one or more of the horizontal spacing distance and the pitch for the live pillars 122 may differ from that of the dummy pillars 136. In some areas of the microelectronic device structure 100 (e.g., at a periphery of the transition areas 134) a peripheral dummy pillar 136 and a neighboring, peripheral live pillar 122 may be arranged, relative to one another, with substantially the same horizontal spacing distance and/or pitch as in the array(s) of the dummy pillars 136 and/or as in the array(s) of live pillars 122.

The dummy pillars 136 are positioned so as to be spaced at least a predetermined minimum separation distance 140 from the source/drain contacts 124, such as from a horizontally outermost portion of the source/drain contacts 124. In some embodiments, the source/drain contacts 124 has sidewall(s) that are not perfectly vertical, such that the source/drain contacts 124 may taper in horizontal width through some or all elevations of the stack structure 102. In some of these embodiments, the source/drain contacts 124 projects outward at one or more positions along the sidewall of the source/drain contact 124. These outward most points may be referred to herein as a “bow” (bow 142) of the source/drain contact 124. The minimum separation distance 140 spacing the source/drain contact 124 from a neighboring one of the dummy pillars 136 may be defined at an elevation of the bow 142 of the source/drain contact 124. The minimum separation distance 140 may be selected or otherwise configured to facilitate no physical contact and no electrical communication between the source/drain contacts 124 and the dummy pillars 136.

The dummy pillars 136 extend at least through the upper deck 114, and the dummy pillars 136 may not extend into the lower deck 110 or may extend only partially into the lower deck 110. In embodiments in which a third or more deck is included in the stack structure 102, between the lower deck 110 and the upper deck 114, the dummy pillars 136 may extend through or into any of these intermediate decks, or the dummy pillars 136 may extend only partially into an intermediate deck. Accordingly, whether the stack structure 102 includes two or more than two decks, the dummy pillar 136 may extend only or primarily through deck(s) above the lower deck 110 (e.g., only or primarily through the upper deck 114) of the stack structure 102.

As used herein, a dummy pillar 136 extending “only through the upper deck 114” means and refers to the dummy pillar 136 having a lowest point at or below a lowest surface of the upper deck 114, but not below an uppermost surface of an additional deck (e.g., the lower deck 110) below the upper deck 114.

As used herein, a dummy pillar 136 extending “only through deck(s) above the lower deck 110” means and refers to the dummy pillar 136 having a lowest point at or below a lowest surface of the deck(s) above the lower deck 110, but not below an uppermost surface of the lower deck 110.

As used herein, a dummy pillar 136 extending “primarily through the upper deck 114” means and refers to the dummy pillar 136 having at least a majority of its entire height defined in elevations of the upper deck 114. Therefore, no more than about 50% of the height of the dummy pillar 136 may be in elevations below the upper deck 114.

As used herein, a dummy pillar 136 extending “primarily through deck(s) above the lower deck 110” means and refers to the dummy pillar 136 having at least a majority of its entire height defined in elevations of the deck(s) that are above the lower deck 110. Therefore, no more than about 50% of the height of the dummy pillar 136 may be in elevations of the lower deck 110.

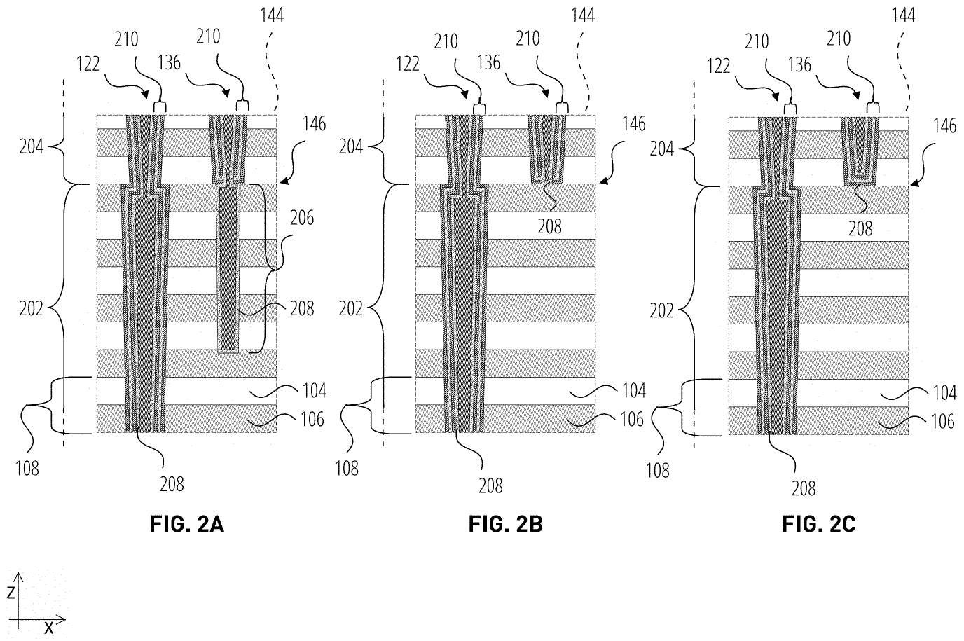

For example, and with reference to FIG. 2A through FIG. 2C illustrated are enlarged cross-sectional views of the portion of the microelectronic device structure 100 of FIG. 1, indicated by box 144, in accordance with various embodiments of the disclosure. These illustrations include a first deck 202 of the tiers 108 and a second deck 204 of the tiers 108 above the first deck 202. The first deck 202 may represent the lower deck 110 of FIG. 1, and the second deck 204 may represent the upper deck 114 of FIG. 1, such as in embodiments in which the stack structure 102 (FIG. 1) includes two decks of the tiers 108. In embodiments in which the stack structure 102 (FIG. 1) includes more than two decks, the first deck 202 may represent the lower deck 110 of FIG. 1, and the second deck 204 may represent an intermediate deck above the lower deck 110 but below the upper deck 114. In other more-than-two-deck embodiments, the second deck 204 may represent the upper deck 114 of FIG. 1, and the first deck 202 may represent an intermediate deck below the upper deck 114 but above the lower deck 110 of FIG. 1.

With regard to FIG. 2A, in some embodiments, a lowermost portion of each or some of the dummy pillars 136 extends into the first deck 202 from the second deck 204 above the first deck 202. In such embodiments, an extension 206 of the dummy pillar 136 extends below a lowermost surface of the second deck 204, into and through an interdeck portion 146, and into the first deck 202.

In some such embodiments, a channel material 208 of the dummy pillar 136 extends through and below outer cell material(s) 210 of the dummy pillar 136. The channel material 208 may define an outer sidewall of the extension 206 of the dummy pillar 136. In contrast, the channel material 208 of the live pillars 122 may not be exposed through the outer cell material(s) 210.

As another example, and with reference to FIG. 2B and FIG. 2C, each or some of the dummy pillars 136 may extend only through the second deck 204 and not into or through the first deck 202 (additional deck(s) below, if any). The dummy pillar 136 may also not extend through the interdeck portion 146.

With reference to FIG. 2B, in some embodiments the channel material 208 extends through the outer cell material(s) 210 of the dummy pillar 136, as illustrated in FIG. 2B, but does not extend below the outer cell material(s) 210. Accordingly, a lowermost surface of the channel material 208 may be substantially coplanar with a lowermost surface of the outer cell material(s) 210.

With reference to FIG. 2C, in some embodiments the channel material 208 does not extend through the outer cell material(s) 210 of the dummy pillar 136. The outer cell material(s) 210 may vertically underlay (e.g., vertically underlie) and horizontally surround the channel material 208 in the vicinity of the interdeck portion 146.

Accordingly, at least the lower deck 110 (FIG. 1)—and, in some embodiments, one or more intermediate deck(s)—may be substantially free of the dummy pillars 136 (e.g., as in FIG. 2A, in embodiments in which the first deck 202 represents the lower deck 110 of FIG. 1) or may be wholly free of the dummy pillars 136 (e.g., as in FIG. 2B and FIG. 2C, in embodiments in which the first deck 202 represents the lower deck 110 or an intermediate deck, or as in FIG. 2A, in embodiments in which the first deck 202 represents an intermediate deck). In embodiments in which the dummy pillars 136 have an extension 206 (FIG. 2A) protruding into the lower deck 110 (FIG. 1) (e.g., as in FIG. 2A, in embodiments in which the first deck 202 represents the lower deck 110 of FIG. 1), the extension 206 may extend through less about half the quantity of tiers 108 of the lower deck 110.

Returning reference to FIG. 1, with the dummy pillars 136 disposed in only or primarily the upper deck 114—or in only or primarily the upper deck 114 and intermediate deck(s)—some or all of the tiers 108 of the lower deck 110 (and any other region or deck below the upper deck 114) may vertically space the dummy pillars 136 from the source/drain region 116. In contrast, the live pillars 122 may extend through an entirety of a height of the stack structure 102, through all decks (e.g., the upper deck 114, intermediate deck(s), if any, and the lower deck 110), and to or into the source/drain region 116.

With the dummy pillars 136 solely or primarily in deck(s) above the lower deck 110 (e.g., the upper deck 114), the dummy pillars 136 do not extend to elevations in proximity to the conductive landing structures 126 and do not extend near to where the source/drain contacts 124 come into physical contact with the conductive landing structures 126. Therefore, the dummy pillars 136 are disposed and otherwise configured not to physically or functionally interfere with either the source/drain contacts 124 or the conductive landing structures 126. For example, by not forming the dummy pillars 136 in close proximity to or within the cross-sectional area of the source/drain contacts 124, the risk of any material (e.g., polymer material) of the dummy pillars 136 accumulating in contact with the source/drain contacts 124 and/or the conductive landing structures 126 and causing contact failure or negatively impacting electrical conductivity is avoided.

In some embodiments, at or near the interdeck portion 146 an interdeck dielectric region may be included, which may be formed of and include insulative material such as the same or different insulative material as the material of the insulative structures 104 of the tiers 108. An interdeck dielectric region may be included vertically between neighboring decks of the stack structure 102. The interdeck dielectric region(s) may be significantly thicker than any individual one of the insulative structures 104 of the tiers 108.

Slit structures 148 extend through the stack structure 102 (e.g., through all decks, including the upper deck 114 and the lower deck 110) and divide the microelectronic device structure 100 into blocks 138. The slit structures 148 may also extend to or through the doped material 118 of the source/drain region 116 in a base structure 112.

The slit structure 148 may include an insulative liner 150 (e.g., formed of and including one or more insulative material(s)) and a nonconductive fill material 152 (e.g., any one or more of the aforementioned insulative material(s) and/or a semiconductive material, such as polysilicon). In some embodiments, sidewalls of the conductive structures 106 are laterally recessed, relative to the insulative structures 104, along the slit structure 148. In such embodiments, the insulative liner 150 may laterally extend in correspondence with the lateral recesses of the conductive structures 106.

Each of the blocks 138 may include an array of the live pillars 122, and the sequence of blocks 138 may form the live pillar array portion 120 of the microelectronic device structure 100. Longitudinally adjacent the live pillar array portion 120, either with or without intervening features, may be one or more staircase portions that include staircase structure(s) having steps defined by ends (e.g., sidewalls) of at least some of the tiers 108. Operative, electrical contacts may be included in the staircase portion to form electrical connection to the various conductive structures 106 of the stack structure 102.

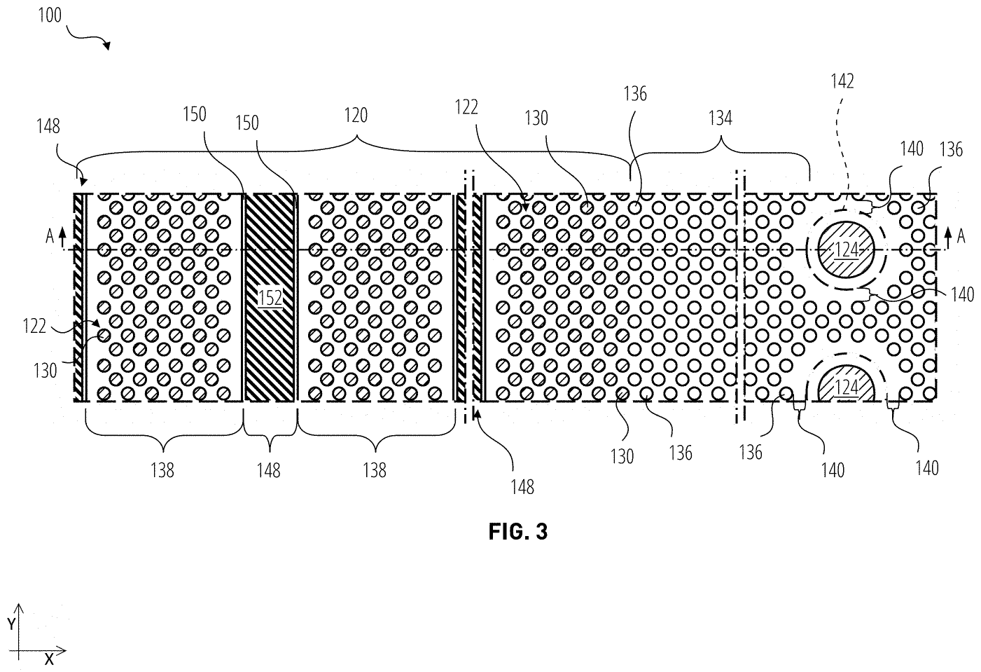

FIG. 3 illustrates a top-view perspective of the microelectronic device structure 100 of FIG. 1, such that the view of FIG. 1 may be a cross-sectional view taken along section line A-A of FIG. 3. The minimum separation distance 140 between a particular dummy pillar 136 and the horizontally outermost portion of the source/drain contacts 124 (e.g., the bow 142) may be maintained wholly laterally around each of the source/drain contacts 124. Where a distance separating neighboring source/drain contacts 124 is great enough to include dummy pillars 136 while maintaining the minimum separation distance 140, one or more dummy pillars 136 may be included between neighboring source/drain contacts 124, as illustrated in FIG. 3. Accordingly, the dummy pillars 136 may be included, not only in the transition area 134 that is horizontally between the source/drain contacts 124 and the live pillar array portion 120, but also in additional areas longitudinally or laterally adjacent the source/drain contacts 124, provided the minimum separation distance 140 is maintained.

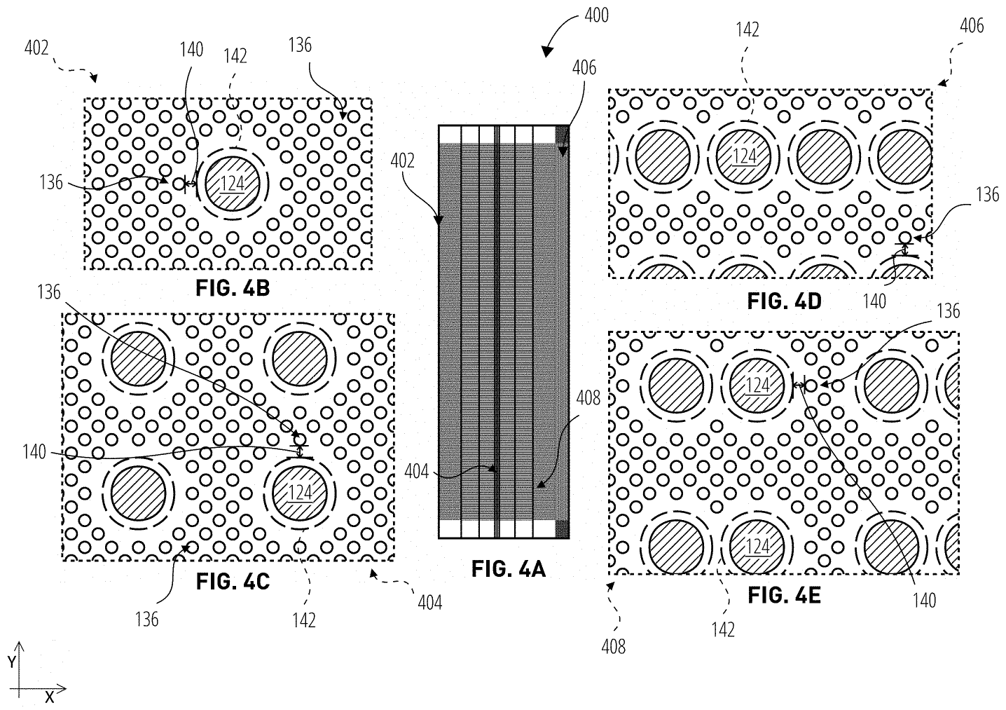

The particular minimum separation distance 140 selected may be tailored according to the area of the microelectronic device in which the dummy pillars 136 and the source/drain contacts 124 are positioned. For example, FIG. 4A illustrates a microelectronic device 400 that includes multiple areas, such as periphery areas 402 (e.g., areas peripheral to the live pillar array portions 120 (FIG. 1) of the microelectronic device 400), plane separation areas 404 (e.g., areas separating plane(s) for independent word line unit control), ROM areas 406 (e.g., areas with dummy pillars 136 adjacent source/drain contacts 124 that access read only memory (ROM) features), and bit line exit areas 408 (e.g., areas where conductive lines that are in operational communication with the live pillars 122 (FIG. 1), such as via the conductive plugs 130, transition away from the live pillar array portion 120 (FIG. 1)). Possible examples of such areas are illustrated, schematically, in enlarged views in FIG. 4B (the periphery area 402), FIG. 4C (the plane separation area 404), FIG. 4D (the ROM area 406), and FIG. 4E (the bit line exit area 408), respectively.

The quantity and arrangement of the source/drain contacts 124 in each of these areas may be different and may be tailored according to design needs for the microelectronic device 400. For example, with regard to the periphery area 402 of FIG. 4B and the plane separation area 404 of FIG. 4C, the source/drain contacts 124 may be relatively distanced from one another with dummy pillars 136 fully around each of the source/drain contacts 124. As another example, with regard to the ROM area 406 of FIG. 4D and the bit line exit area 408 of FIG. 4E, some of the source/drain contacts 124 may be relatively closer together such that there are no dummy pillars 136 between the closest neighboring source/drain contacts 124, but also so that there are dummy pillars 136 between more distanced neighboring source/drain contacts 124. Accordingly, the dummy pillars 136 may be laterally adjacent, longitudinally adjacent, and/or wholly laterally surround the source/drain contacts 124 provided the appropriate minimum separation distance 140 is maintained. The dummy pillars 136 may be included horizontally adjacent each source/drain contact 124 in the microelectronic device 400 (FIG. 4A) or at least some of the source/drain contacts 124.

The minimum separation distance 140 in a particular area may be selected or otherwise configured according to design needs for the microelectronic device 400. For example, in the periphery area 402 (FIG. 4B) the minimum separation distance 140 may be formed to be at least about 50 nm, while in the bit line exit area 408 (FIG. 4E), the minimum separation distance 140 may be formed to be at least about 25 nm.

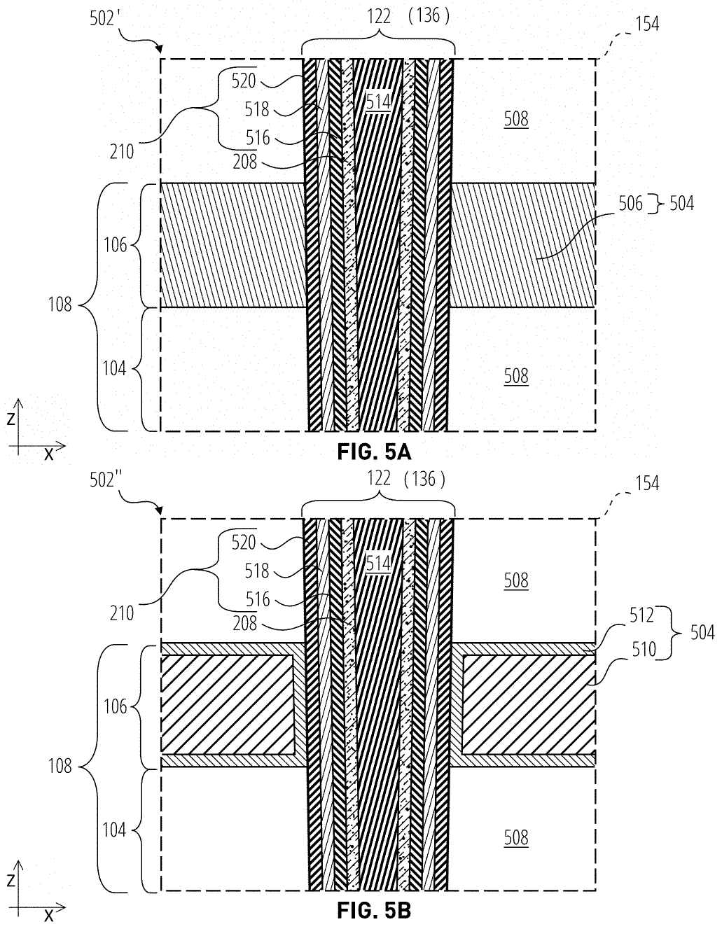

With reference to FIG. 5A and FIG. 5B, schematically illustrated are enlarged cross-sectional views of memory cells (e.g., memory cell 502′ of FIG. 5A, memory cell 502″ of FIG. 5B) that may be provided in the microelectronic device structure 100 of FIG. 1. The illustrated portions of FIG. 5A and FIG. 5B correspond to the area indicated by box 154 of FIG. 1. Reference herein to one “memory cell 502” or multiple “memory cells 502” equally refers to one or multiple of any of the illustrated memory cell 502′ of FIG. 5A and/or the illustrated memory cell 502″ of FIG. 5B.

The formation of the memory cells 502 may be effectuated by the live pillars 122 of the microelectronic device structure 100 of FIG. 1. In the discussions herein, descriptions of the materials and sub-structures of one live pillar 122 may equally apply to the materials and sub-structures of any or all of the live pillars 122 of a microelectronic device structure of any embodiment of this disclosure (e.g., the microelectronic device structure 100 of FIG. 1). Moreover, because the dummy pillars 136 may be formed of substantially the same materials and sub-structures as the live pillars 122, at least in the upper deck 114 (FIG. 1) above the vicinity of the interdeck portion 146 (FIG. 1), the descriptions and illustrations of FIG. 5A and FIG. 5B equally apply to the dummy pillars 136 in the upper deck 114 (FIG. 1) with the exception that the dummy pillars 136 may not effectuate formation of functional memory cells.

The memory cells 502 are in the vicinity of at least one of the tiers 108, with at least one of the insulative structures 104 vertically adjacent at least one of the conductive structures 106. In some embodiments, such as that illustrated in FIG. 5A, conductive material(s) 504 of the conductive structures 106 consist essentially of, or consist of, a single conductive material or a homogenous combination of conductive materials either of which is represented by a conductive material 506 illustrated in FIG. 5A. The conductive material 506 may be directly adjacent insulative material 508 of the insulative structure 104, e.g., without a distinguishable conductive liner.

In other embodiments, such as that illustrated in FIG. 5B, the conductive materials 504 of some or all of the conductive structures 106 include a conductive metal 510 surrounded at least in part by a conductive liner material 512. The conductive liner material 512 may be directly adjacent upper and lower surfaces of neighboring insulative structures 104, respectively. The conductive metal 510 may be directly vertically between portions of the conductive liner material 512.

The conductive material(s) 504 may be any of the conductive materials described above with regard to the conductive structures 106. The insulative material 508 may be any of the insulative materials described above with regard to the insulative structures 104.

Memory cells 502″ having the structure of FIG. 5B may be formed, in part, through a so-called “replacement gate” process, discussed further below. The conductive liner material 512 may comprise, for example, a seed material that enables formation of the conductive metal 510 during the replacement-gate process. The conductive liner material 512 may be formed of and include, for example, a metal (e.g., titanium, tantalum), a metal nitride (e.g., tungsten nitride, titanium nitride, tantalum nitride), or another material. In some embodiments, the conductive liner material 512 comprises titanium nitride, and the conductive metal 510 comprises tungsten.

With continued reference to FIG. 5A and FIG. 5B, adjacent the tiers 108 are materials of the pillars. That is, in the upper deck 114 (FIG. 1), the materials of the live pillars 122 are adjacent the tiers 108 of both the upper deck 114 (FIG. 1) and the lower deck 110 (FIG. 1); and, in the lower deck 110 (FIG. 1), the materials of the dummy pillars 136 are adjacent the tiers 108 of the upper deck 114 (FIG. 1) and, in some embodiments, some uppermost tiers 108 in the lower deck 110 (FIG. 1).

As illustrated in FIG. 5A and FIG. 5B, each of the live pillar 122 (and the dummy pillar 136) includes outer cell material(s) 210 that horizontally surround a channel material 208, which horizontally surrounds an insulative material 514 at an axial center of the live pillar 122.

The insulative material 514 (e.g., at the core of the live pillar 122 and at the core of the dummy pillar 136) may be formed of and include an insulative material such as, for example, phosphosilicate glass (PSG), borosilicate glass (BSG), fluorosilicate glass (FSG), borophosphosilicate glass (BPSG), silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide, a nitride material, (e.g., silicon nitride (Si₃N₄)), an oxynitride (e.g., silicon oxynitride), a dielectric carbon nitride material (e.g., silicon carbon nitride (SiCN)), a dielectric carboxynitride material (e.g., silicon carboxynitride (SiOCN)), an insulative gas (e.g., air), or combinations thereof. In some embodiments, the insulative material 514 comprises silicon dioxide.

Both the live pillars 122 and the dummy pillars 136 also include the channel material 208, which may horizontally surround the insulative material 514. Therefore, the channel material 208 may be horizontally interposed between the insulative material 514 and the tiers 108 of the deck(s) through which the pillars (e.g., the live pillars 122, the dummy pillars 136) extend. The channel material 208 may be formed of and include one or more of a semiconductor material (at least one elemental semiconductor material, such as polycrystalline silicon; at least one III-V compound semiconductor material, at least one II-VI compound semiconductor material, at least one organic semiconductor material, GaAs, InP, GaP, GaN, other semiconductor materials), and an oxide semiconductor material. In some embodiments, the channel material 208 includes amorphous silicon or polysilicon. In some embodiments, the channel material 208 includes a doped semiconductor material.

The outer cell material(s) 210 may horizontally surround the channel material 208. The outer cell material(s) 210 may include a tunnel dielectric material 516 (also referred to as a “tunneling dielectric material”), which may be horizontally adjacent the channel material 208; a memory material 518, which may be horizontally adjacent the tunnel dielectric material 516; and a dielectric blocking material 520 (also referred to as a “charge blocking material”), which may be horizontally adjacent the memory material 518. In some embodiments, a dielectric barrier material is also horizontally interposed (e.g., directly horizontally interposed) between the dielectric blocking material 520 and the tiers 108 of the stack structure 102.

In the live pillars 122, the outer cell material(s) 210—including the tunnel dielectric material 516, the memory material 518, the dielectric blocking material 520, and, if present, the dielectric blocking material 520—may also extend to and/or into the doped material 118 of the base structure 112. In the dummy pillars 136, the outer cell material(s) 210 may be substantially within only the upper deck 114, as illustrated in FIG. 2A through FIG. 2C, such that they may not extend into the lower deck 110.

With continued reference to FIG. 5A and FIG. 5B, the tunnel dielectric material 516 may be formed of and include a dielectric material through which charge tunneling can be performed (e.g., in the live pillars 122) under suitable electrical bias conditions, such as through hot-carrier injection or by Fowler-Nordheim tunneling induced charge transfer. The tunnel dielectric material 516 may be formed of and include one or more of silicon oxide, silicon nitride, silicon oxynitride, dielectric metal oxides (e.g., aluminum oxide and hafnium oxide), dielectric metal oxynitride, dielectric metal silicates, alloys thereof, and/or combinations thereof. In some embodiments, the tunnel dielectric material 516 comprises silicon dioxide or silicon oxynitride.

The memory material 518 may comprise a charge trapping material or a conductive material. The memory material 518 may be formed of and include one or more of silicon nitride, silicon oxynitride, polysilicon (e.g., doped polysilicon), a conductive material (e.g., tungsten, molybdenum, tantalum, titanium, platinum, ruthenium, and alloys thereof, or a metal silicide such as tungsten silicide, molybdenum silicide, tantalum silicide, titanium silicide, nickel silicide, cobalt silicide, or a combination thereof), a semiconductive material polycrystalline or amorphous semiconductor material including at least one elemental semiconductor element or at least one compound semiconductor material, conductive nanoparticles (e.g., ruthenium nanoparticles), metal dots. In some embodiments, the memory material 518 comprises silicon nitride.

The dielectric blocking material 520 may be formed of and include one or more dielectric materials, such as, for example, one or more of an oxide (e.g., silicon dioxide), a nitride (e.g., silicon nitride), an oxynitride (e.g., silicon oxynitride), or another material. The material(s) of the dielectric blocking material 520 may be formed as one or more distinctive material regions (e.g., sub-regions, layers). In some embodiments, the dielectric blocking material 520 comprises a single material region, which may be formed of and include silicon oxynitride. In other embodiments, the dielectric blocking material 520 comprises a structure configured as an oxide-nitride-oxide (ONO) structure, with a series of material regions (e.g., sub-regions, layers) formed of and including, respectively, an oxide (e.g., silicon dioxide), a nitride (e.g., silicon nitride), and an oxide again (e.g., silicon dioxide).

In some embodiments, the tunnel dielectric material 516, the memory material 518, and the dielectric blocking material 520 together may form a structure configured to trap a charge (e.g., in association with the live pillars 122), such as, for example, an oxide-nitride-oxide (ONO) structure. In some such embodiments, for both the live pillars 122 and the dummy pillars 136, the tunnel dielectric material 516 comprises silicon dioxide, the memory material 518 comprises silicon nitride, and the dielectric blocking material 520 comprises silicon dioxide.

In embodiments including a dielectric barrier material, the dielectric barrier material may be formed of and include one or more of a metal oxide (e.g., one or more of aluminum oxide, hafnium oxide, zirconium oxide, lanthanum oxide, yttrium oxide, tantalum oxide, gadolinium oxide, niobium oxide, titanium oxide), a dielectric silicide (e.g., aluminum silicide, hafnium silicate, zirconium silicate, lanthanum silicide, yttrium silicide, tantalum silicide), and a dielectric nitride (e.g., aluminum nitride, hafnium nitride, lanthanum nitride, yttrium nitride, tantalum nitride).

In some embodiments of memory cells of the disclosure, such as with the memory cell 502′ of FIG. 5A and the memory cell 502″ of FIG. 5B, the channel material 208 is horizontally interposed between the insulative material 514 and the tunnel dielectric material 516. The tunnel dielectric material 516 may be horizontally interposed between the channel material 208 and the memory material 518; and the memory material 518 may be horizontally interposed between the tunnel dielectric material 516 and the dielectric blocking material 520. In some such embodiments, the dielectric blocking material 520 is horizontally interposed between the memory material 518 and a dielectric barrier material (not illustrated, but which, if included, may be included within the outer cell material(s) 210), and the dielectric barrier material is directly adjacent the conductive structure 106 and the insulative structure 104 of the tier 108. In other such embodiments, the dielectric blocking material 520 is directly horizontally interposed between the memory material 518 and the tier 108.

To effectuate the memory cell 502 (e.g., the memory cell 502′ of FIG. 5A, the memory cell 502″ of FIG. 5B), one of the conductive structures 106 horizontally surrounds (e.g., encircles) the materials of the live pillar 122 (e.g., FIG. 3), which is also in physical contact with one of the conductive plugs 130 (FIG. 1) above and the source/drain region 116 below. In embodiments corresponding to the memory cell 502′ of FIG. 5A, the conductive material 506 horizontally surrounds the materials of the live pillar 122 (e.g., FIG. 3); whereas, in embodiments corresponding to the memory cell 502″ of FIG. 5B, both the conductive metal 510 and the conductive liner material 512 horizontally surround the materials of the live pillar 122 (e.g., FIG. 3).

With regard to the dummy pillars 136, the conductive structures 106 also horizontally surround (e.g., encircle) the material of each dummy pillar 136, but a functional memory cell 502 is not effectuated at least due to, e.g., lack of the conductive plug 130 (FIG. 1) on the dummy pillar 136 and lack of contact between dummy pillar 136 and the source/drain region 116 (FIG. 1).

Accordingly, each of the live pillars 122 (e.g., FIG. 1) may facilitate a string of memory cells 502 extending vertically, or at least partially vertically, through the stack structure 102 (FIG. 1), from the source/drain region 116 (FIG. 1) to a drain region above the stack structure 102, e.g., in the vicinity where the conductive plugs 130 (FIG. 1) are in contact with the live pillars 122.

Accordingly, disclosed is a microelectronic device comprising a stack structure. The stack structure comprises a vertically alternating sequence of insulative structures and conductive structures arranged in tiers and the tiers arranged in decks. At least one live pillar extends through the deck of the stack structure to a source/drain region below the stack structure. The at least one live pillar comprises a channel material. At least one source/drain contact extends through the decks of the stack structure. In a transition area horizontally between the at least one live pillar and the at least one source/drain contact, at least one dummy pillar extends through at least one of the decks of the stack structure. The at least one dummy pillar is separated from the source/drain region by at least one of the tiers of a lower deck of the decks. The at least one dummy pillar is spaced from the at least one source/drain contact.

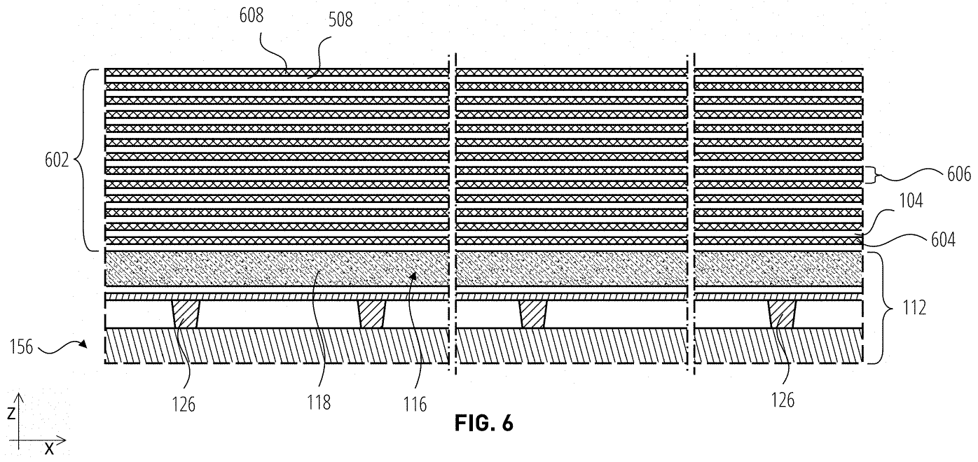

With reference to FIG. 6 through FIG. 17, illustrated are various stages for a method of forming a microelectronic device, such as one including the microelectronic device structure 100 previously described with reference to FIG. 1 and/or the microelectronic device 400 previously described with reference to FIG. 4A.

With reference to FIG. 6, a lower deck 602 is formed on the base structure 112, in which the conductive landing structures 126 and the doped material 118 of the source/drain region 116 may have already been formed. In other embodiments, any or all of the features of the base structure 112 are sacrificial at this stage and may be replaced with final features later in the fabrication process.

The lower deck 602 is formed to include a vertically alternating sequence of the insulative structures 104 and other structures (e.g., sacrificial structures 604) arranged in tiers 606. The sacrificial structures 604 may be formed at levels of the lower deck 602 that will eventually be replaced with or otherwise converted into the conductive structures 106 (FIG. 1).

Sacrificial material 608 of the sacrificial structures 604 may be selected or otherwise formulated to be selectively removable (e.g., selectively etchable) relative to the insulative material 508 of the insulative structures 104. In some embodiments, the insulative material 508 comprises silicon dioxide and the sacrificial material 608 comprises silicon nitride.

To form the lower deck 602, formation (e.g., deposition) of the insulative material 508 of the insulative structures 104 may be alternated with formation (e.g., deposition) of the sacrificial material 608 of the sacrificial structures 604.

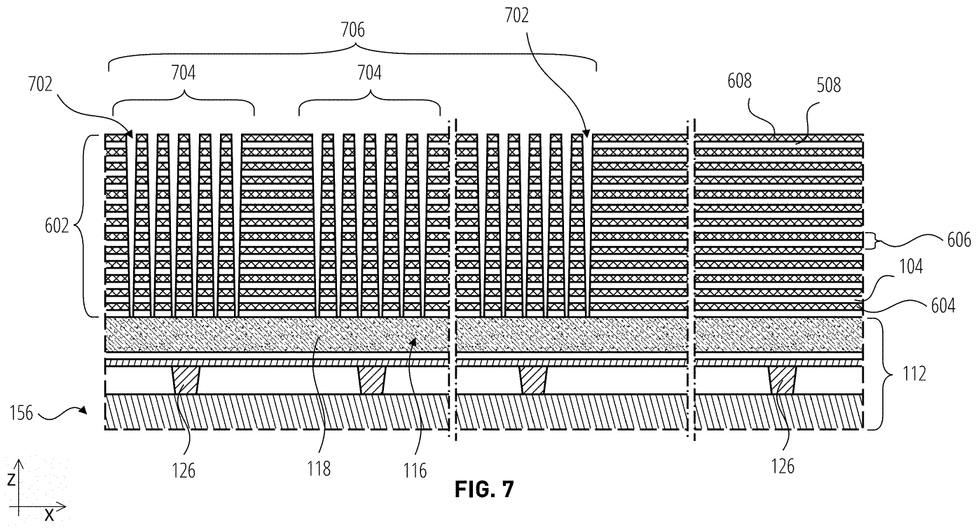

With reference to FIG. 7, openings 702 may be formed (e.g., etched) through the lower deck 602 and to or into the base structure 112. The arrangement of the openings 702 may correspond to the arrangement of the live pillars 122 (see FIG. 1 and FIG. 3) to be formed in the live pillar array portion 120 (FIG. 1 and FIG. 3). Thus, in some embodiments, the openings 702 may be formed through the lower deck 602 substantially only in areas that will become the blocks 138 (FIG. 1) of the microelectronic device structure 100 (FIG. 1). For example, the openings 702 may be formed in block areas 704 of a live pillar array area 706. The openings 702 may not be formed in areas of the lower deck 602 that are horizontally adjacent the live pillar array area 706, as illustrated in FIG. 7, such as where the source/drain contacts 124 (FIG. 1) will be formed.

In embodiments in which the stack structure 102 (FIG. 1) includes more than two decks and in which the dummy pillars 136 (FIG. 1) are substantially or only in the upper deck 114 (FIG. 1), the intermediate deck(s) may be formed on the lower deck 602 may repeating the stages illustrated in FIGS. 6 and 7 for each intermediate deck.

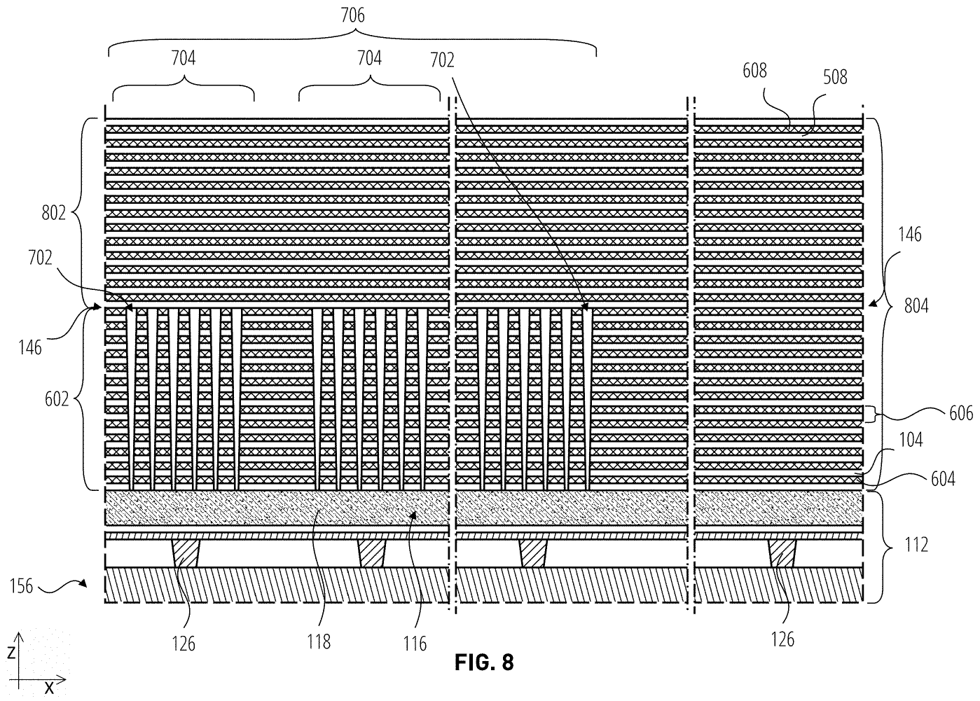

With reference to FIG. 8, an upper deck 802 is formed above the lower deck 110. The upper deck 802, like the lower deck 602, is formed to include a vertically alternating sequence of the insulative structures 104 and the other structures (e.g., the sacrificial structures 604) arranged in the tiers 606. The formation of the second deck (e.g., the upper deck 114) may be substantially the same as formation of the lower deck 602.

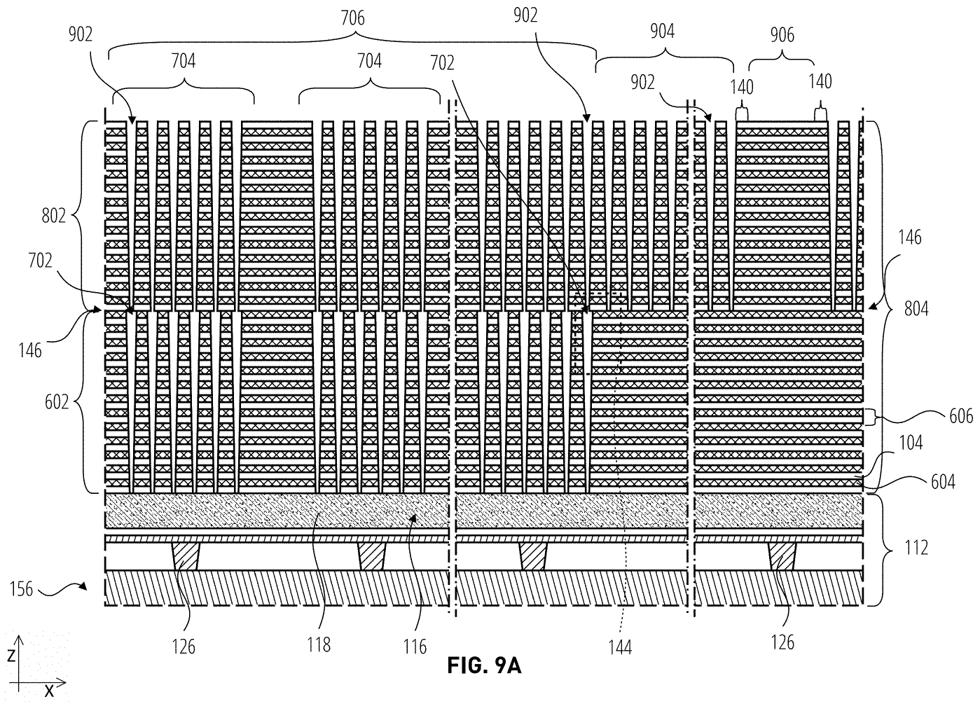

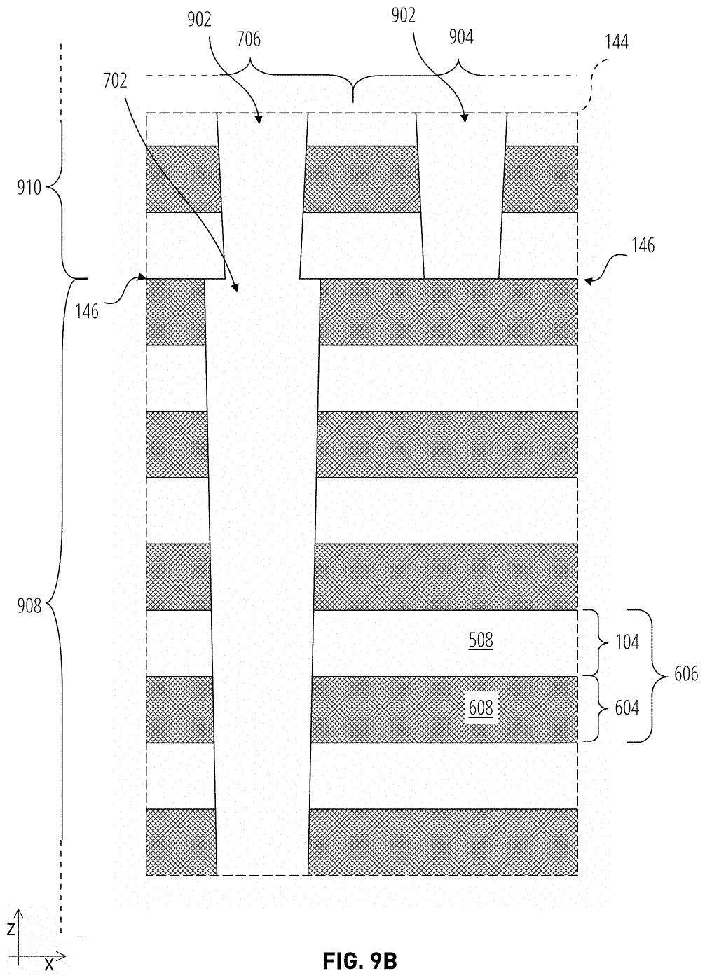

With reference to FIG. 9A, openings 902 may be formed (e.g., etched) through the upper deck 802. The arrangement of the openings 902 through the upper deck 802 may correspond to the arrangement of the live pillars 122 (FIG. 1) and the dummy pillars 136. Accordingly, the openings 902 through the upper deck 802 may be formed in the live pillar array area 706 and open to the openings 702 in the lower deck 602 (and any other intermediate deck(s) below the upper deck 802); and, the openings 902 may be formed in a transition area 904 that will become the transition area 134 of FIG. 1. The openings 902 may not be formed in contact areas 906, where the source/drain contacts 124 will be formed, and may not be formed in the areas reserved for the minimum separation distances 140.

In embodiments in which the stack structure 102 (FIG. 1) includes more than two decks and in which the dummy pillars 136 extend into intermediate deck(s), these intermediate deck(s) may be sequentially formed by the stages illustrated in FIG. 8 and FIG. 9A, before a final repeating of these stages to form the upper deck 802 in the elevations corresponding to the upper deck 114 of FIG. 1.

With reference to FIG. 9B, schematically illustrated is an enlarged cross-sectional view of the portion of the structure of FIG. 9A corresponding to box 144. Illustrated is the interdeck portion 146 between a first deck 908 (that includes substantially only the openings 702 for the lower portion(s) of the live pillars 122 (FIG. 1)) and a second deck 204 (that includes the openings 902 for both the dummy pillars 136 (FIG. 1) and the upper portion(s) of the live pillars 122 (FIG. 1)). The first deck 908 may correspond to the lower deck 110 of FIG. 1, and the second deck 910 may correspond to the upper deck 114 of FIG. 1, such as in embodiments in which the microelectronic device structure 100 (FIG. 1) to be formed includes two decks of the tiers 108 (FIG. 1). In embodiments in which the microelectronic device structure 100 (FIG. 1) includes more than two decks, the first deck 908 may correspond to the lower deck 110 of FIG. 1, and the second deck 910 may correspond to an intermediate deck above the lower deck 110 but below the upper deck 114 (FIG. 1). In other more-than-two-deck embodiments, the second deck 910 may correspond to the upper deck 114 of FIG. 1, and the first deck 908 may correspond to an intermediate deck below the upper deck 114 but above the lower deck 110 of FIG. 1.

As illustrated in FIG. 9B, some of the openings 902 extend through the second deck 910, and each of these openings 902 open to and communicate with a respective one of the openings 702 through the first deck 908. These combined openings (illustrated on the left side of FIG. 9B) provide pillar openings through an entire height of the stack structure 804 (FIG. 9A) and are the pillar openings in which the live pillars 122 (FIG. 1) will be formed. Others of the openings 902 extend only, or substantially only, through the second deck 910 and do not communicate with lower openings (e.g., the openings 702). These other openings (illustrated on the right side of FIG. 9B) provide pillar openings through only a portion of the height of the stack structure and are the pillar openings in which the dummy pillars 136 (FIG. 1) will be formed.

Because the openings 902 for the dummy pillars 136 (FIG. 1) do not extend substantially into the first deck 908 (e.g., the lower deck 602), when the dummy pillars 136 (FIG. 1) are formed, they are separated from the conductive landing structures 126 (FIG. 1) by at least multiple tiers 108 (FIG. 1) of the lower deck 110 (FIG. 1). Accordingly, unintended interaction between the dummy pillars 136 (FIG. 1) and the conductive landing structures 126 (FIG. 1) may be avoided.

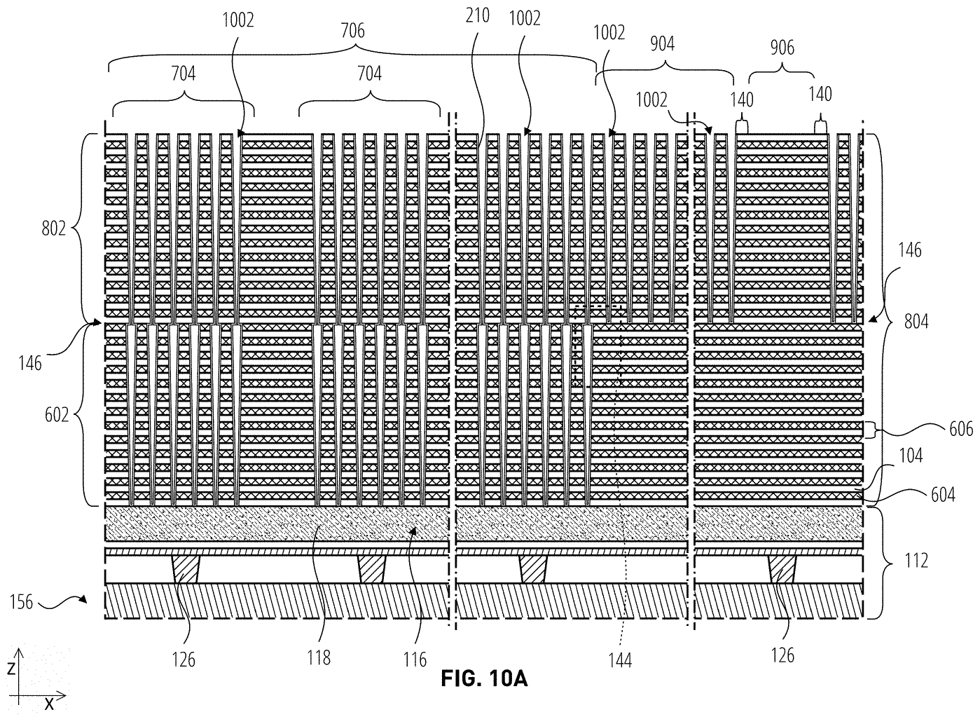

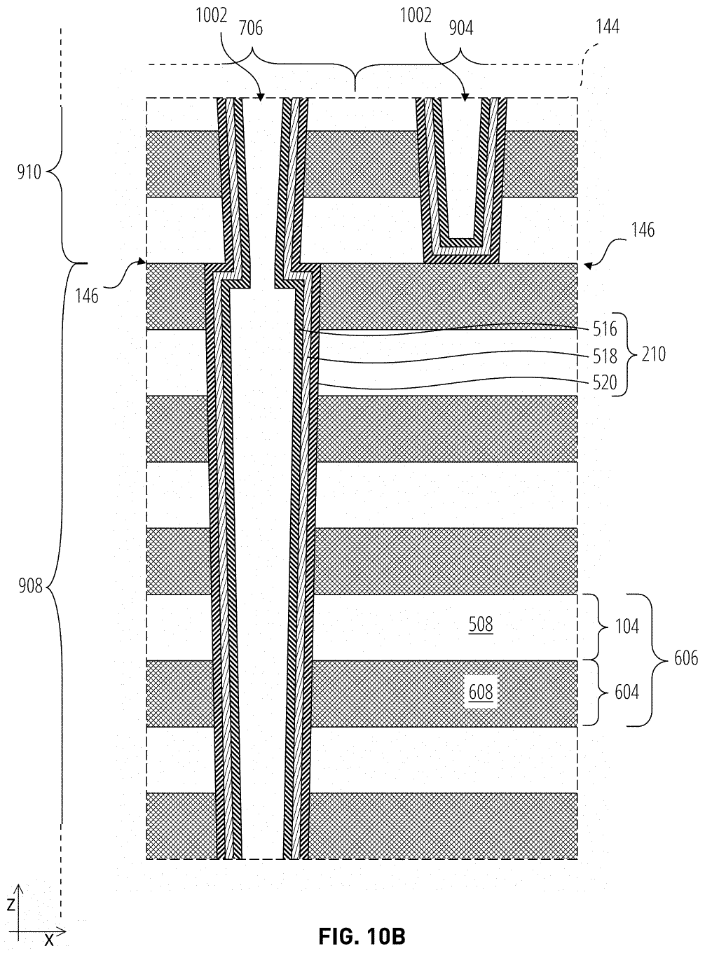

With reference to FIG. 10A and FIG. 10B (an enlarged schematic, cross-sectional illustration of the portion of the structure of FIG. 10A corresponding to box 144), the outer cell material(s) 210 are formed (e.g., conformally deposited) in the openings 902 (FIG. 9B) and the openings 702 (FIG. 9B). Accordingly, as illustrated in FIG. 10B, the dielectric blocking material 520, the memory material 518, and the tunnel dielectric material 516 may be formed (e.g., conformally deposited) in sequence, covering the sidewall and base of the openings 902 (FIG. 9B) and the openings 702 (FIG. 9B). In embodiments in which the outer cell material(s) 210 include a dielectric barrier material, that material may be formed (e.g., conformally deposited) prior to forming the dielectric blocking material 520.

Forming the outer cell material(s) 210 may leave openings 1002 substantially lined by the tunnel dielectric material 516. In the openings 1002 in the transition area 904 (FIG. 10A), the outer cell material(s) 210 may extend substantially only through the second deck 910 (FIG. 10B) (e.g., the upper deck 802 (FIG. 10A)) without extending through the interdeck portion 146 or into the first deck 908 (FIG. 10B) (e.g., the lower deck 602 (FIG. 10A)). In the openings 1002 in the live pillar array area 706 (FIG. 10A), the outer cell materials 210 may extend through all decks.

The outer cell material(s) 210 in the transition areas 904 (e.g., for the dummy pillars 136 (FIG. 1)) and the outer cell material(s) 210 in the live pillar array areas 706 (e.g., for the live pillars 122 (FIG. 1)) may be formed substantially concurrently. This may minimize fabrication cost and complexity. However, the disclosure is not so limited. In other embodiments, the outer cell material(s) 210 in the live pillar array areas 706 may be formed in separate stage(s) than the formation of the outer cell material(s) 210 in the transition areas 904.

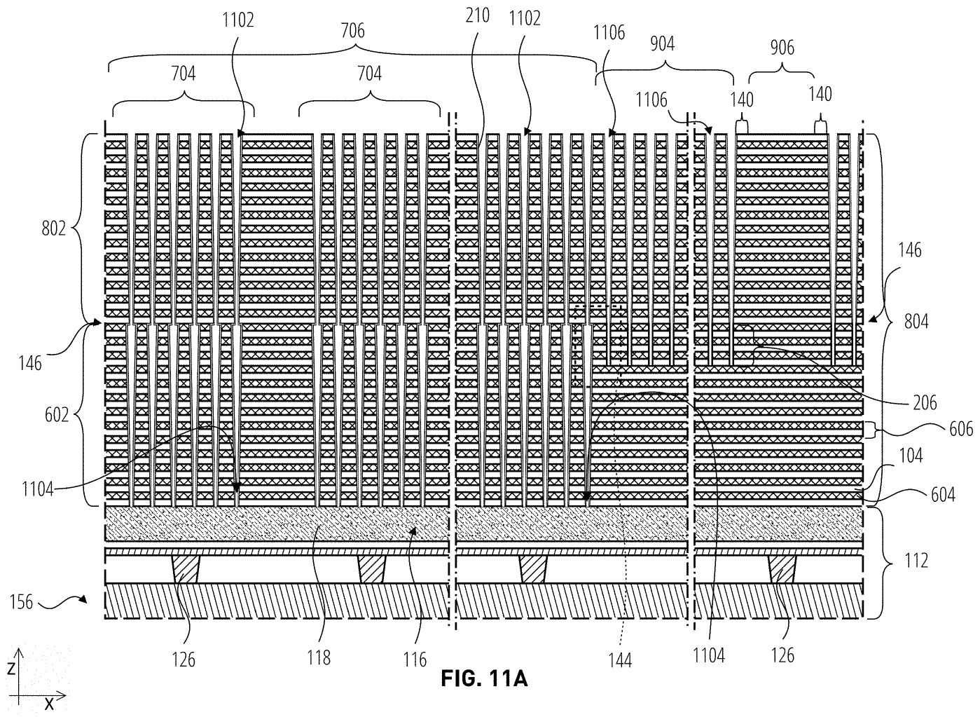

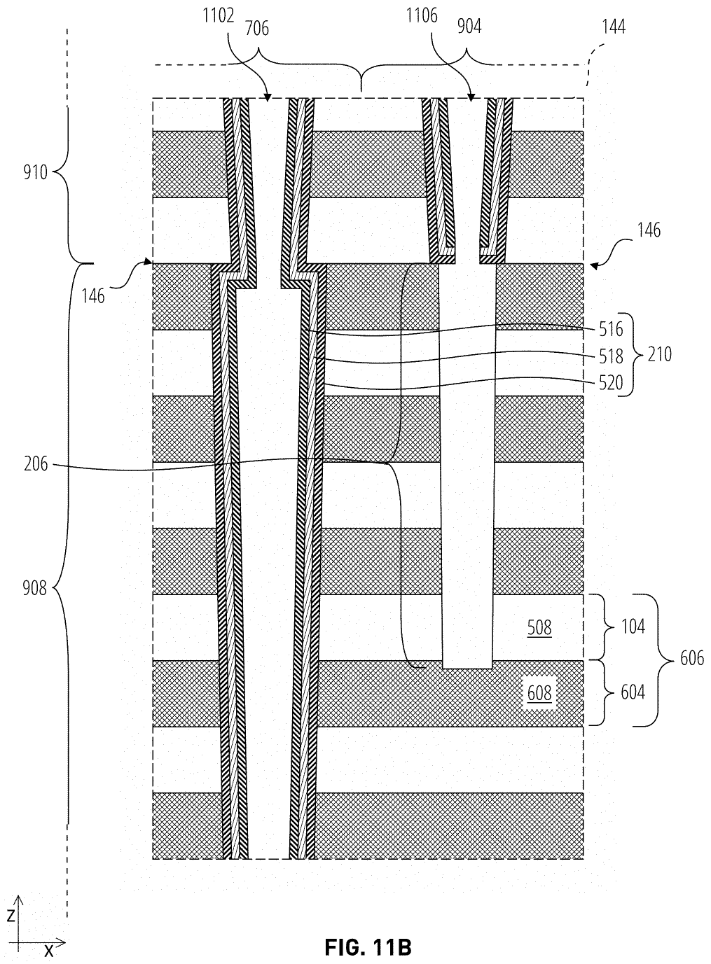

To expose portions of the base structure 112 at the base of the openings 1002 in the live pillar array area 706 so that the channel material 208 (FIG. 2A through FIG. 2C) of the live pillars 122 (FIG. 1) may be formed in contact with the source/drain region 116 (FIG. 1), an opening may be formed (e.g., directionally etched, such as directionally dry etched) through the outer cell material(s) 210 at the base of each of the openings 1002 in the live pillar array area 706. As illustrated in FIG. 11A, the resulting openings 1102 in the live pillar array area 706 yield exposed areas 1104 of the source/drain region 116 at the base of the openings 1102.

With regard to the transition areas 904, in some embodiments, the outer cell material(s) 210 is not etched. In some such embodiments, the outer cell material(s) 210 remains substantially covering the sidewall and base (e.g., floor) of the openings 1002 as illustrated in FIG. 10B. A resulting fabricated structure may be consistent with the structure illustrated in FIG. 2C and described above.

In other embodiments, before, during, or after etching through the outer cell material(s) 210 in the live pillar array area 706, the outer cell material(s) 210 in the transition area 904 may also be etched (e.g., directionally etched, such as directionally dry etched) to form an opening extending through the outer cell material(s) 210, as illustrated in FIG. 11B (which is an enlarged schematic, cross-sectional illustration of the portion of the structure of FIG. 11A corresponding to box 144). In some such embodiments, the etching continues into the materials of the tiers 606 of the first deck 908, forming an extended opening 1106 with an extension 206 below the second deck 910.

The extension 206 may extend through or partially into one or more tiers 108 of the first deck 908 (e.g., the lower deck 602). In some embodiments, the vertical dimension of the extension 206 is less than half the height of the first deck 908 (e.g., the lower deck 602). The extension 206 may not extend to the vicinity of the source/drain region 116, and multiple tiers 606, not etched in the transition area 904, separate the base of the extensions 206 from the source/drain region 116 with the conductive landing structures 126 even further separated from the extensions 206.

The extension 206 may result from concurrently etching the outer cell material(s) 210 in both the live pillar array areas 706 and the transition areas 904. The vertical dimension of the extension 206 may be based on the duration of the etching process needed to form the exposed areas 1104 (FIG. 11A) in the live pillar array areas 706. In other embodiments, the vertical dimension of the extension 206 may be selected and tailored according to design needs.

A resulting fabricated structure, as described further below, may be consistent with the structure illustrated in FIG. 2A. In other embodiments, etching the outer cell material(s) 210 in the transition area 904 forms an opening through the outer cell material(s) 210 that does not extend into the tiers 606. A resulting fabricated structure may be consistent with the structure illustrated in FIG. 2B.

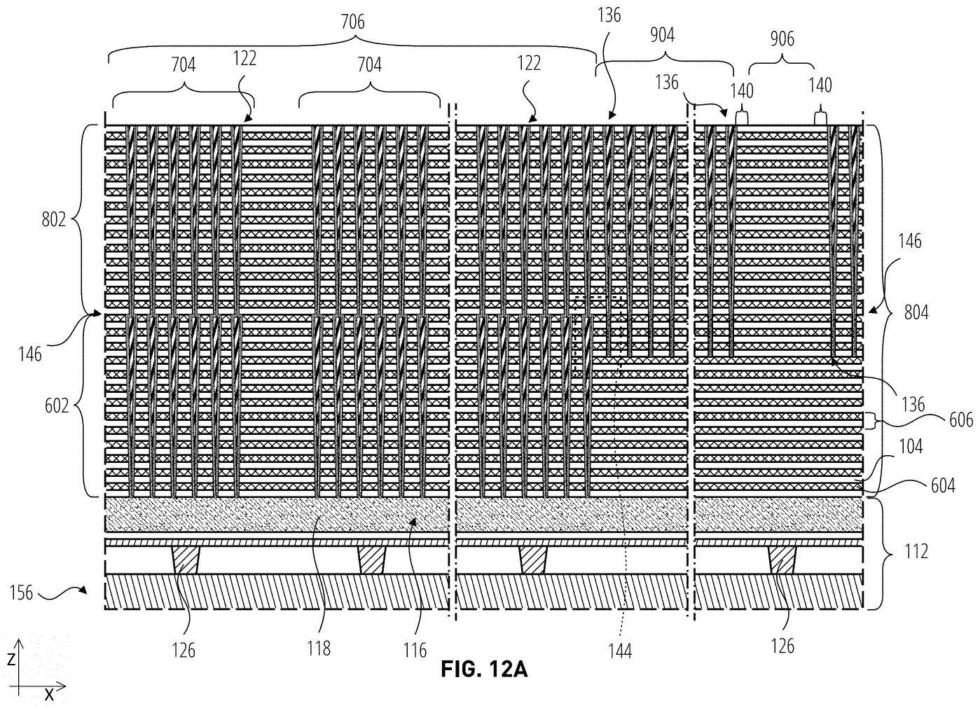

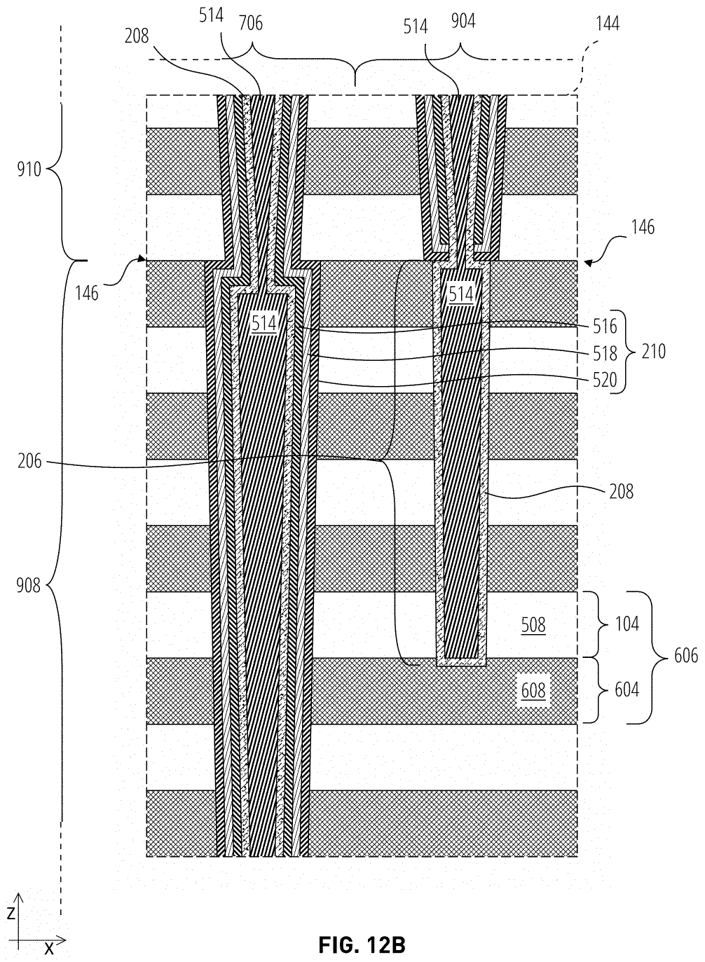

With reference to FIG. 12A and FIG. 12B (an enlarged schematic, cross-sectional illustration of the portion of the structure of FIG. 12A corresponding to box 144), the channel material 208 may be formed (e.g., conformally deposited) on the outer cell material(s) 210, and the insulative material 514 may be formed on the channel material 208 to complete the materials of the live pillars 122 in the live pillar array area 706 and the dummy pillars 136 in the transition area 904

In the live pillars 122 of the live pillar array area 706, the channel material 208 may extend continuously through an entire height of all decks of the stack structure 804 (FIG. 12A) to physically contact the source/drain region 116. In the dummy pillars 136 the channel material 208 extends through at least the upper deck 802 but not into, nor not substantially through, the lower deck 602.

In embodiments in which etching through the outer cell material(s) 210 in the transition area 904 formed the extension 206, the channel material 208 may line the sidewall and base of the extension 206, as illustrated in FIG. 12B and consistent with the dummy pillar 136 illustrated in FIG. 2A. Therefore, the channel material 208 in the extension 206 may be in direct physical contact with the insulative material 508 and the sacrificial material 608 of the tiers 606. The insulative material 514 may substantially fill the remainder of the extension 206.

In embodiments in which the outer cell material(s) 210 in the transition area 904 were etched to form an opening that does not extend into the first deck 908 (e.g., the lower deck 110), the channel material 208 extends through the outer cell material(s) 210 but does not extend below the second deck 910 (e.g., the upper deck 802) or into the first deck 908 (e.g., the lower deck 602), forming a structure consistent with the dummy pillar 136 illustrated in FIG. 2B.

In embodiments in which the outer cell material(s) 210 in the transition area 904 were not etched at their base, the channel materials 208 horizontally surrounds and vertically underlays the channel material 208, forming a structure consistent with the dummy pillar 136 illustrated in FIG. 2C. None of the materials of the dummy pillar 136 may extend below the second deck 910 (e.g., the upper deck 802) or into the first deck 908 (e.g., the lower deck 602).

With regard to the live pillars 122 of the live pillar array areas 706, the stages of FIG. 10A through FIG. 12B including forming the materials of the live pillars 122 (FIG. 1) as a structure with each material extending continuously through an entire height of the stack structure 804. In other embodiments, some or all of the materials of the live pillars 122 may be formed in multiple sections (e.g., one section per deck). For example, after forming the openings 702 (FIG. 7) through the lower deck 602, the outer cell material(s) 210 may be formed in only the openings 702 (FIG. 7) of the lower deck 602, etched to form the exposed areas 1104 (FIG. 11A), and the channel material 208 and the insulative material 514 may be formed on the outer cell material(s) 210 to form a first section of the live pillars 122 extending through the lower deck 602. Then, the tiers 606 of the next deck (e.g., an intermediate deck, the upper deck 802) may be formed as described above with regard to FIG. 8. The openings 902 may be formed through the next deck (e.g., the upper deck 802) to expose the upper surface(s) of materials of the lower section of the live pillars 122, including the channel material 208. Additional amounts of the outer cell material(s) 210 may be formed in the openings 902, over the first section of the live pillars 122, and openings may be etched through the outer cell material(s) 210 to expose at least the channel material 208 of the first section of the live pillars 122. Additional amounts of the channel material 208 and the insulative material 514 may be consecutively formed to complete second sections of the live pillars 122 above the first sections, the second sections extending through the next deck (e.g., an intermediate deck, the upper deck 802). In embodiments including more than two decks, the tier 606 formation, openings 902 formation, outer cell material(s) 210 formation, opening through the outer cell material(s) 210, and channel material 208 and insulative material 514 formation stages may be repeated for each successive deck until completing the formation of the upper deck 114.

While the foregoing stages and described illustrations include forming features of the live pillar array area 706 concurrently with like features of the dummy pillars 136, for those deck(s) that include both live pillars 122 (FIG. 1) and dummy pillars 136 (FIG. 1), the disclosure is not so limited. In other embodiments, the features (e.g., openings, materials) of the live pillars 122 may be formed separately from the features (e.g., openings, materials) of the dummy pillars 136, in any order or in any combination of concurrent and successive stages. For example, the openings 902 in the live pillar array area 706 may be formed in a different etching act than an etching act forming the openings 902 in the transition areas 904.

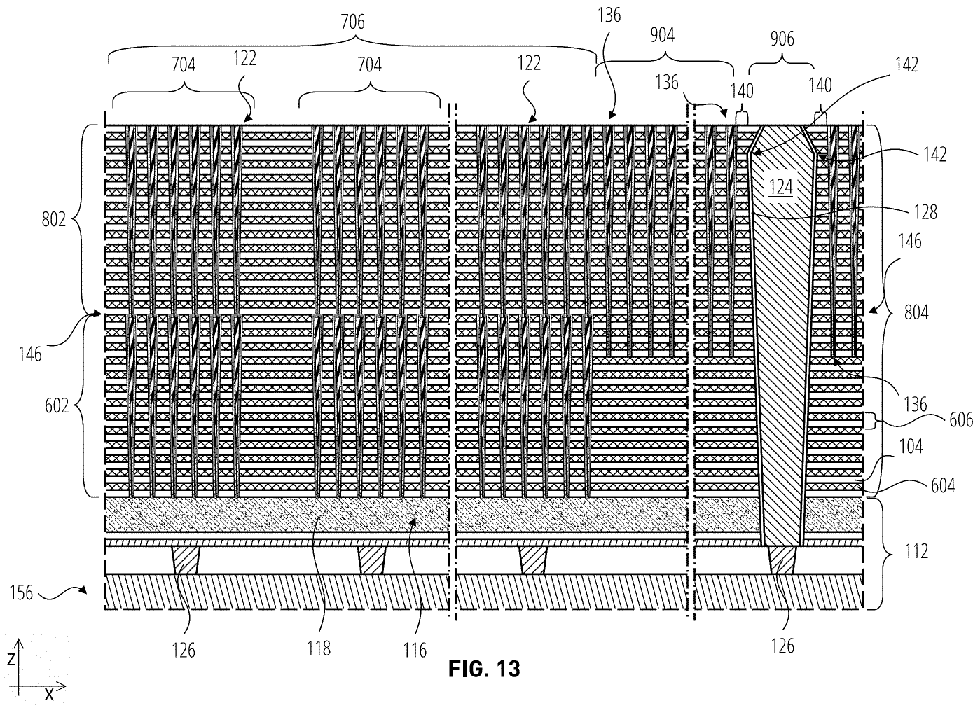

With reference to FIG. 13, the source/drain contacts 124 may be formed through the stack structure 804 in the contact areas 906 so that the source/drain contacts 124 are spaced (e.g., at an elevation of the maximum horizontal extension, e.g., the bow 142) from the nearest dummy pillars 136 by at least the minimum separation distance 140. Forming the source/drain contacts 124 may include forming (e.g., etching) openings through the stack structure 804 and through the source/drain region 116 to expose at least a portion of the conductive landing structures 126. A dielectric liner 128 may be formed in these openings and selectively etched, if necessary, to re-expose the portions of the conductive landing structures 126. Conductive material(s) of the source/drain contacts 124 may then be formed (e.g., deposited) to complete the formation of the source/drain contacts 124.

The materials of the dummy pillars 136 may exhibit substantially compressive stresses while the materials of the source/drain contacts 124 exhibit substantially tensile stress, and the compressive stresses exhibited by the dummy pillars 136 may negate or lessen the effects that may otherwise be caused by the formation of the source/drain contacts 124. Therefore, the presence of the dummy pillars 136 during formation of the source/drain contacts 124 may provide enhanced structural integrity to the stack structure 804, and bending of the live pillars 122 (e.g., bending away from vertical) may be avoided or lessened.

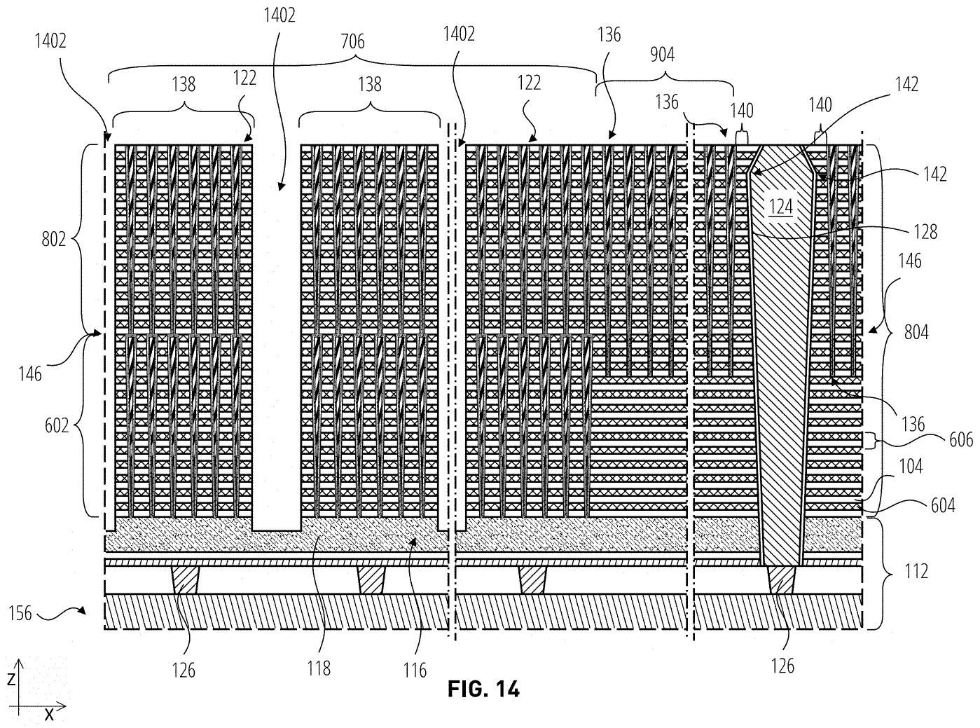

With reference to FIG. 14, a slit 1402 is formed (e.g., etched) for each slit structure 148 (FIG. 1) to be formed in the microelectronic device structure 100 (FIG. 1), defining dividing the blocks 138 in the block areas 704 (FIG. 13) that include the live pillars 122. Each slit 1402 may extend through all decks (e.g., the lower deck 602, the upper decks 802) and to or into the base structure 112 (e.g., the doped material 118 of the source/drain region 116). In the slit 1402, ends of the sacrificial structures 604 and the insulative structures 104 of the lower deck 602 are exposed.

With the presence of the dummy pillars 136 having inhibited bending of the live pillars 122, the slits 1402 may be more reliably formed in the areas between the blocks 138. Therefore, fabrication challenges such as so-called “top shaving” (e.g., forming a slit 1402 that cuts into an area intended to be part of the block 138 or into the live pillars 122 themselves on one slit-facing side of a block 138) and “rail imbalances” (e.g., forming the slits 1402 so that a greater width of conductive structures 106 remains along one slit-facing side of the block 138 than along the other slit-facing side of the block 138) may be avoided.

In embodiments in which the dummy pillars 136 extend partially into a lower deck (e.g., the lower deck 602) from an upper deck (e.g., the upper deck 114), the dummy pillars 136 may also inhibit delamination between neighboring decks (e.g., the upper deck 802 and the lower deck 602).

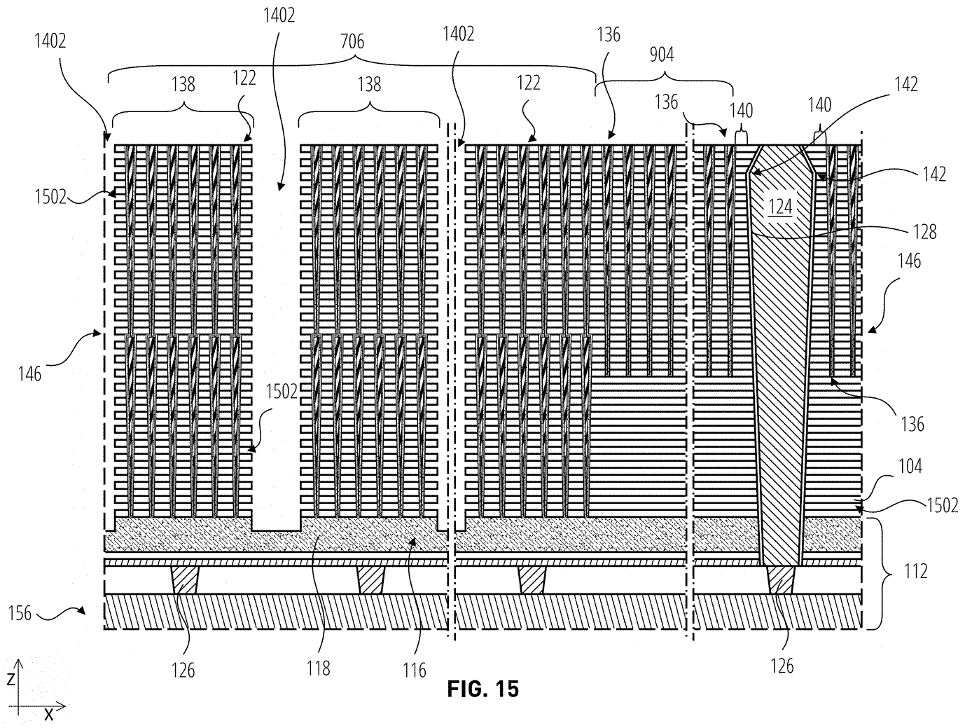

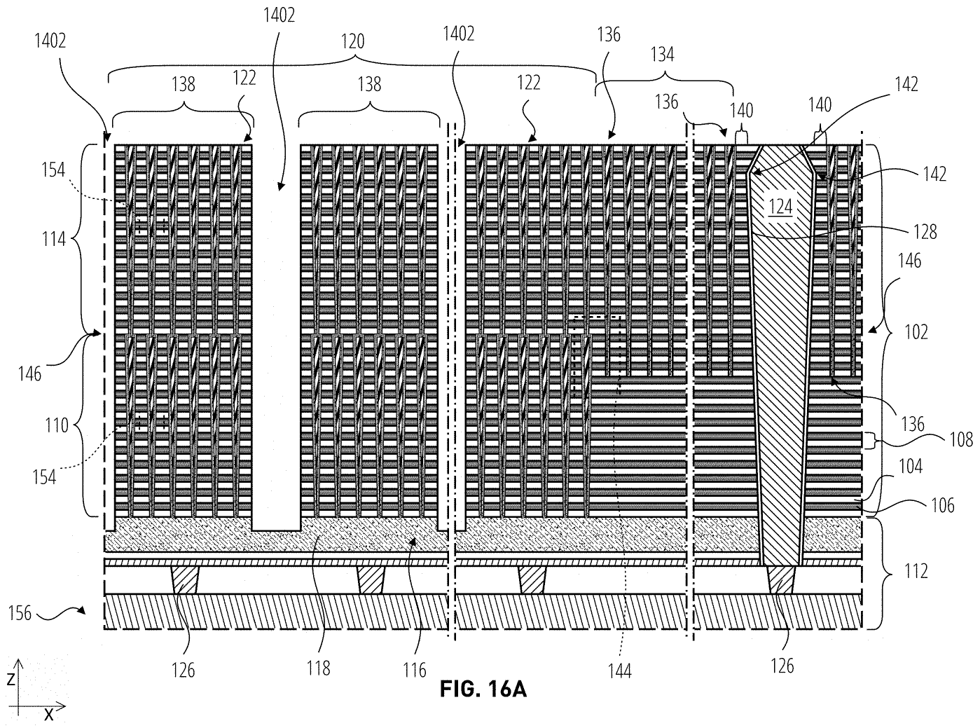

A “replacement gate” process may be performed, via the slits 1402, to at least partially (e.g., substantially) exhume the sacrificial material 608 (e.g., FIG. 12B)—and therefore the sacrificial structures 604—leaving voids 1502 (e.g., void spaces, gaps) between the insulative structures 104, as illustrated in FIG. 15.

During the replacement gate process, the presence of the dummy pillars 136 may also inhibit bending or other deformation of the live pillars 122 and/or delamination of the decks, particularly in embodiments in which the dummy pillars 136 include the extensions 206 (FIG. 12B).

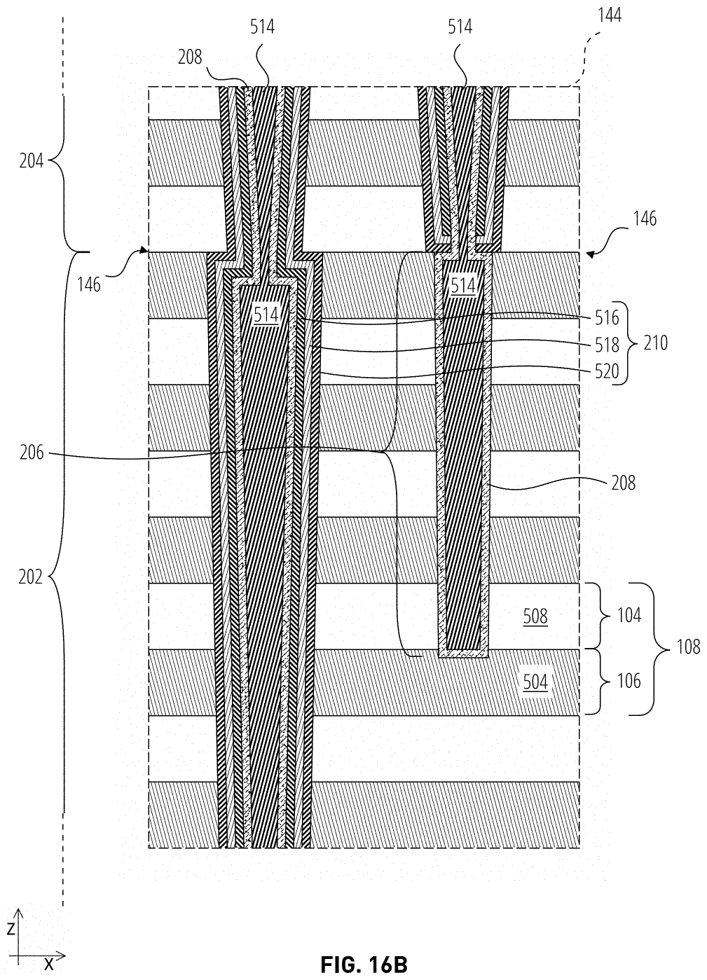

In the voids 1502, the conductive material(s) 504 are formed, as illustrated in FIG. 16A to form the conductive structures 106 of the tiers 108 of the stack structure 102. For example, in accordance with the memory cells 502′ previously described with reference to FIG. 5A, the conductive material 506 (FIG. 5A) may be formed in the voids 1502, directly on the insulative material 508. The conductive material 506 may also be formed directly on exposed portions of the dielectric blocking material 520 (or other outermost outer cell material(s) 210) of the live pillars 122 and the dummy pillars 136.

As another example, in accordance with the memory cells 502″ previously described with reference to FIG. 5B, the conductive liner material 512 (FIG. 5B) may be formed directly on the insulative material 508 before forming the conductive metal 510 (FIG. 5B) on the conductive liner material 512 to form the conductive material(s) 504. The conductive liner material 512 may also be formed directly on exposed portions of the dielectric blocking material 520 (or other outermost outer cell material(s) 210) of the live pillars 122 and the dummy pillars 136 and on the channel material 208 of the extensions 206, in embodiments in which the dummy pillars 136 include the extensions 206.

In embodiments in which the dummy pillars 136 include the extensions 206 (FIG. 2A, FIG. 12B), the conductive material(s) 504 (e.g., the conductive material 506 (FIG. 5A) or the conductive liner material 512 (FIG. 5B)) may also be formed directly on the channel material 208 that defines an outermost surface of the extensions 206, as illustrated in FIG. 16B (an enlarged schematic, cross-sectional illustration of the portion of the structure of FIG. 16A corresponding to box 144). The direct physical contact of the channel material 208 with the conductive material(s) 504 may not be operationally problematic because the dummy pillars 136 are not electrically active structures in the microelectronic device structure 100 (FIG. 1).

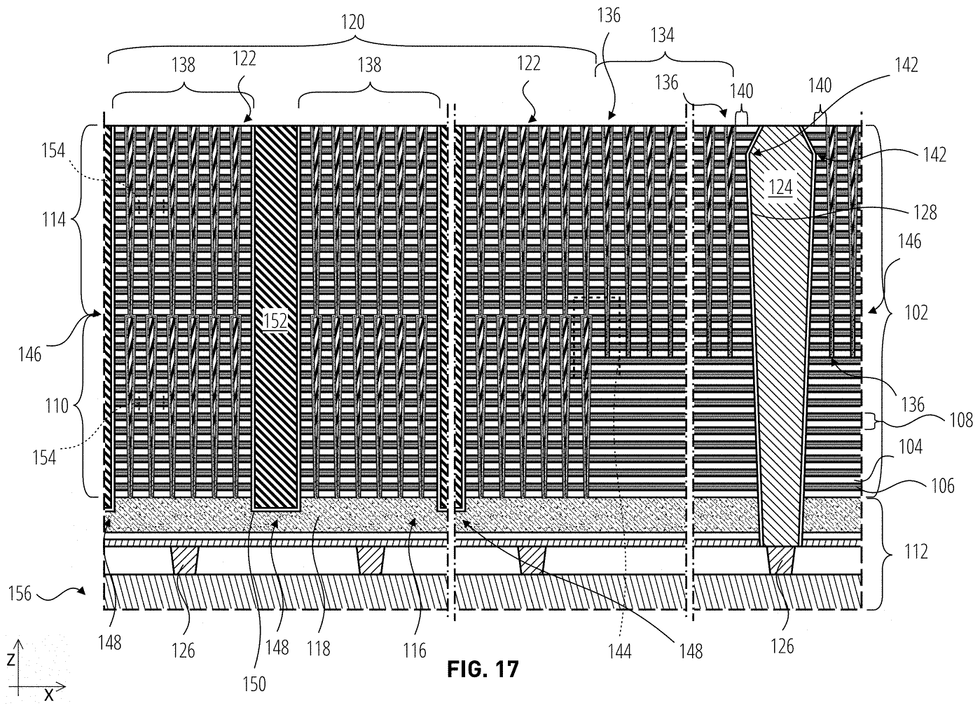

With reference to FIG. 17, the insulative liner 150 may be formed (e.g., deposited) in the slits 1402 (FIG. 16A), on sidewalls of the tiers 108 of the stack structure 102. The nonconductive fill material 152 may be formed (e.g., deposited) to at least partially (e.g., substantially) fill a remaining volume between the insulative liner 150 to complete the slit structures 148.

The conductive plugs 130 (FIG. 1) may be formed on the live pillars 122, as illustrated in FIG. 1. Because the dummy pillars 136 may have inhibited bending of the live pillars 122 and the blocks 138 during fabrication, the conductive plugs 130 may be formed with more reliable alignment with the live pillars 122.

Because the dummy pillars 136 are not operatively active, no conductive plugs 130 are formed in electrical communication with the dummy pillars 136.

Accordingly, disclosed is a method of forming a microelectronic device. The method comprises forming a tiered stack structure on a base structure. The tiered stack structure comprises a vertically alternating sequence of insulative structures and other structures arranged in tiers. In a pillar array area of the tiered stack structure, live pillars are formed. The live pillars comprise a channel material extending, through an entire vertical height of the tiered stack structure, to a source/drain region of the base structure. In an additional area horizontally spaced from the pillar array area, at least one source/drain contact is formed. The at least one source/drain contact extends through the entire vertical height of the tiered stack structure. In a transition area horizontally between the pillar array area and the additional area, dummy pillars are formed. The dummy pillars comprise the channel material. The channel material extends through a portion of the entire vertical height of the tiered stack structure. Conductive plugs are formed in electrical communication with the live pillars.

Also disclosed is a microelectronic device comprising a stack structure. The stack structure comprises insulative structures vertically interleaved with conductive structures and arranged in tiers. Blocks of live pillar arrays comprise live pillars extending through the stack structure to a source/drain region below the stack structure. At least one source/drain contact is horizontally spaced from the blocks of the live pillar arrays. The at least one source/drain contact extends through the stack structure to at least one conductive landing structure proximate the source/drain region. At least one dummy pillar is in at least one transition area horizontally between the at least one source/drain contact and the blocks of the live pillar arrays. The at least one dummy pillar is spaced from the at least one source/drain contact and has a lower end vertically above the at least one conductive landing structure.

By any of the foregoing methods, a microelectronic device structure (e.g., the microelectronic device structure 100 of FIG. 1) is formed that includes live pillars 122, extending through a multiple decks of the stack structure 102, and dummy pillars 136, extending partially through the stack structure 102 in transition areas 134 between the live pillars 122 and source/drain contacts 124. The presence of the dummy pillars 136 may facilitate a more reliable formation of the microelectronic device structure 100. Forming the dummy pillars 136 to be separated from the source/drain contacts 124 (e.g., by at least the minimum separation distance 140) and from the conductive landing structures 126 (e.g., by at least multiple tiers 108 of the lower deck 110) ensure the dummy pillars 136 will not interfere with these features; therefore, electrical contact failure may be avoided or lessened.

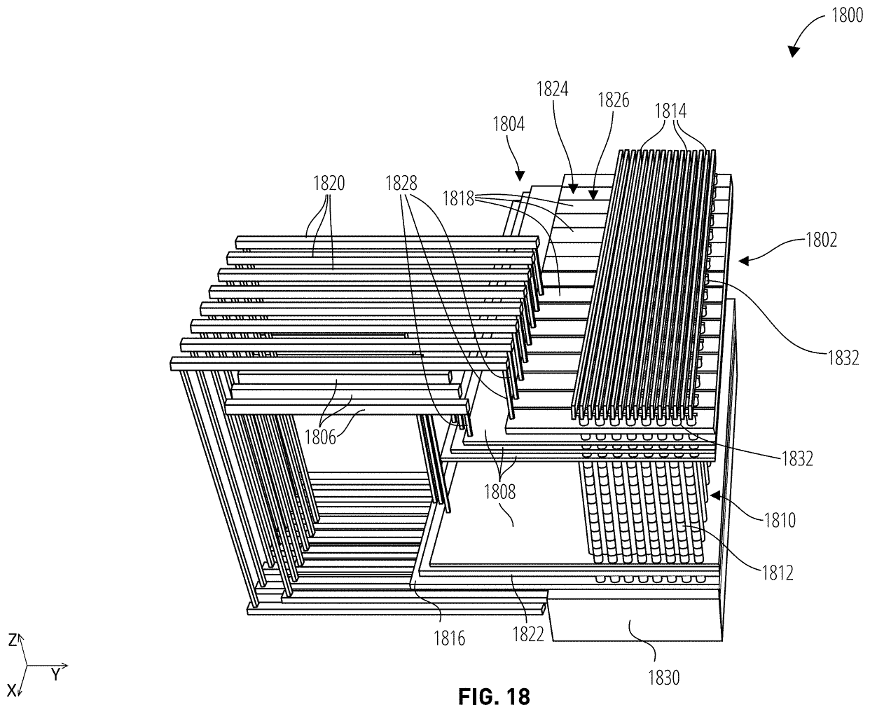

With reference to FIG. 18, illustrated is a partial cutaway, perspective, schematic illustration of a portion of a microelectronic device 1800 (e.g., a memory device, such as a 3D NAND Flash memory device) including a microelectronic device structure 1802. The microelectronic device structure 1802 may be substantially similar to a microelectronic device structure previously described herein (e.g., the microelectronic device structure 100 (FIG. 1) including any one or more of the structures of FIG. 2A through FIG. 2C).

As illustrated in FIG. 18, the microelectronic device structure 1802 may include a staircase structure 1804 (which may correspond to, e.g., the aforementioned staircase portion of the microelectronic device structure 100 of FIG. 1). The staircase structure 1804 may define contact regions for connecting access lines 1806 to conductive tiers 1808 (e.g., conductive layers, conductive plates, such as the conductive structures 106 (FIG. 1)) of a stack structure (e.g., the stack structure 102 (FIG. 1)) in decks (e.g., the lower deck 110 and/or the upper deck 114 of FIG. 1) of the microelectronic device structure 1802.

The microelectronic device structure 1802 may include the live pillars 122 and the dummy pillars 136 (FIG. 1). The live pillars 122 may form strings 1810 of memory cells 1812 (e.g., one or more of the memory cells 502′ of FIG. 5A and/or the memory cells 502″ of FIG. 5B). The live pillars 122 forming the strings 1810 of memory cells 1812 may extend at least somewhat vertically (e.g., in the Z-direction) and orthogonally relative to the conductive tiers 1808, relative to data lines 1814 (e.g., bit lines, digit lines), relative to a source tier 1816 (e.g., the source/drain region 116 of FIG. 1), relative to access lines 1806, relative to first select gates 1818 (e.g., upper select gates, such as drain select gates (SGDs), which may include one or more regions configured as drain-side GIDL region(s)), relative to select lines 1820, and/or relative to one or more second select gates 1822 (e.g., lower select gate(s), such as source select gates (SGSs), which may include one or more regions configured as source-side GIDL region(s)).

The first select gates 1818, the conductive tiers 1808, and the second select gates 1822 may be horizontally divided (e.g., in the X-axis direction) into multiple blocks 1824 (e.g., blocks 138 of FIG. 1) spaced apart (e.g., in the X-axis direction) from one another by slits 1826 (e.g., slit structures 148 of FIG. 1).

Vertical conductive contacts 1828 may electrically couple components to each other, as illustrated. For example, select lines 1820 may be electrically coupled to the first select gates 1818, and the access lines 1806 may be electrically coupled to the conductive tiers 1808.

The microelectronic device 1800 may also include a control unit 1830 positioned under the memory array (e.g., the live pillar array portions 120 of FIG. 1). The control unit 1830 may include control logic devices configured to control various operations of other features (e.g., the memory strings 1810, the memory cells 1812) of the microelectronic device 1800. By way of non-limiting example, the control unit 1830 may include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., string drivers), decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, MUX, error checking and correction (ECC) devices, self-refresh/wear leveling devices, and/or other chip/deck control circuitry. The control unit 1830 may be electrically coupled to the data lines 1814, the source tier 1816, the access lines 1806, the first select gates 1818, and/or the second select gates 1822, for example. In some embodiments, the control unit 1830 may be configured as and/or include CMOS (complementary metal-oxide-semiconductor) circuitry. In such embodiments, the control unit 1830 may be characterized as having a “CMOS under Array” (“CuA”) configuration. Accordingly, the control unit 1830 may be included in the CMOS region 156 of FIG. 1.

The first select gates 1818 may extend horizontally in a first direction (e.g., the Y-axis direction) and may be coupled to respective first groups of strings 1810 of memory cells 1812 at a first end (e.g., an upper end) of the strings 1810. The second select gates 1822 may be formed in a substantially planar configuration and may be coupled to the strings 1810 at a second, opposite end (e.g., a lower end) of the strings 1810 of memory cells 1812.

The data lines 1814 may extend horizontally in a second direction (e.g., in the X-axis direction) that is at an angle (e.g., perpendicular) to the first direction in which the first select gates 1818 extend. The data lines 1814 may be coupled to respective second groups of the strings 1810 at the first end (e.g., the upper end) of the strings 1810. A first group of strings 1810 coupled to a respective first select gate 1818 may share a particular string 1810 with a second group of strings 1810 coupled to a respective data line 1814. Thus, a particular string 1810 may be selected at an intersection of a particular first select gate 1818 and a particular data line 1814. Accordingly, the first select gates 1818 may be used for selecting memory cells 1812 of the strings 1810 of memory cells 1812.

The conductive tiers 1808 (e.g., word lines, word line plates) may extend in respective horizontal planes. The conductive tiers 1808 may be stacked vertically, such that each conductive tier 1808 is coupled to all of the strings 1810 of memory cells 1812 in a respective block 1824, and the strings 1810 of the memory cells 1812 extend vertically through the stack(s) (e.g., decks, such as the lower deck 110 and the upper deck 114 of FIG. 1) of conductive tiers 1808 of the respective block 1824. The conductive tiers 1808 may be coupled to, or may form control gates of, the memory cells 1812 to which the conductive tiers 1808 are coupled. Each conductive tier 1808 may be coupled to one memory cell 1812 of a particular string 1810 of memory cells 1812.

The first select gates 1818 and the second select gates 1822 may operate to select a particular string 1810 of the memory cells 1812 between a particular data line 1814 and the source tier 1816. Thus, a particular memory cell 1812 may be selected and electrically coupled to one of the data lines 1814 by operation of (e.g., by selecting) the appropriate first select gate 1818, second select gate 1822, and the conductive tier 1808 that are coupled to the particular memory cell 1812.

The staircase structure 1804 may be configured to provide electrical connection between the access lines 1806 and the conductive tiers 1808 through the vertical conductive contacts 1828. In other words, a particular level of the conductive tiers 1808 may be selected via one of the access lines 1806 that is in electrical communication with a respective one of the conductive contacts 1828 in electrical communication with the particular conductive tier 1808.

The data lines 1814 may be electrically coupled to the strings 1810 of memory cells 1812 through conductive structures 1832.

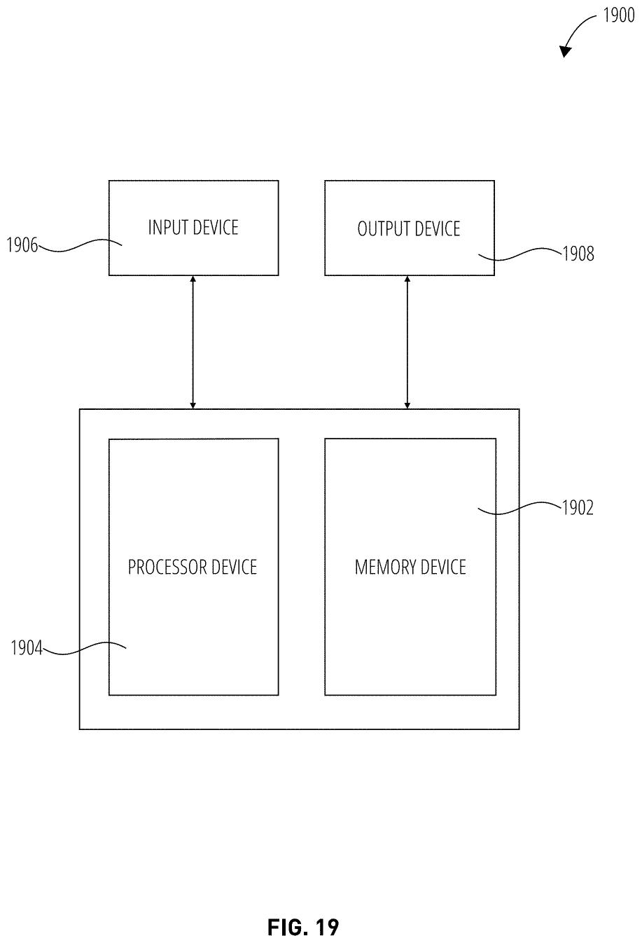

Microelectronic devices (e.g., the microelectronic device 1800) including microelectronic device structures (e.g., the microelectronic device structure 100 of FIG. 1) may be used in embodiments of electronic systems of the disclosure. For example, FIG. 19 is a block diagram of an electronic system 1900, in accordance with embodiments of the disclosure. The electronic system 1900 may comprise, for example, a computer or computer hardware component, a server or other networking hardware component, a cellular telephone, a digital camera, a personal digital assistant (PDA), a portable media (e.g., music) player, a Wi-Fi or cellular-enabled tablet (e.g., an iPAD® or SURFACE® tablet, an electronic book, a navigation device), etc.

The electronic system 1900 includes at least one memory device 1902. The memory device 1902 may include, for example, one or more embodiment(s) of a microelectronic device and/or structure previously described herein (e.g., the microelectronic device 1800 of FIG. 18, the microelectronic device structure 100 of FIG. 1), e.g., with structures formed according to embodiments previously described herein.

The electronic system 1900 may further include at least one electronic signal processor device 1904 (often referred to as a “microprocessor”). The processor device 1904 may, optionally, include an embodiment of a microelectronic device and/or a microelectronic device structure previously described herein (e.g., the microelectronic device 1800 of FIG. 18, the microelectronic device structure 100 of FIG. 1). The electronic system 1900 may further include one or more input devices 1906 for inputting information into the electronic system 1900 by a user, such as, for example, a mouse or other pointing device, a keyboard, a touchpad, a button, or a control panel. The electronic system 1900 may further include one or more output devices 1908 for outputting information (e.g., visual or audio output) to a user such as, for example, a monitor, a display, a printer, an audio output jack, a speaker, etc. In some embodiments, the input device 1906 and the output device 1908 may comprise a single touchscreen device that can be used both to input information into the electronic system 1900 and to output visual information to a user. The input device 1906 and the output device 1908 may communicate electrically with one or more of the memory device 1902 and the electronic signal processor device 1904.

Accordingly, disclosed is an electronic system comprising a three-dimensional memory device, at least one processor in operable communication with the three-dimensional memory device, and at least one peripheral device in operable communication with the at least one processor. The three-dimensional memory device comprises a stack structure comprising conductive structures vertically alternating with insulative structures and arranged in tiers. At least one array of live pillars extends through the stack structure to a source/drain region below the stack structure. Dummy pillars extend, through a portion of the stack structure, in at least one transition area horizontally between the at least one array of live pillars and at least one source/drain contact extending through the stack structure. The dummy pillars are horizontally spaced from the at least one source/drain contact and are vertically spaced from the source/drain region.

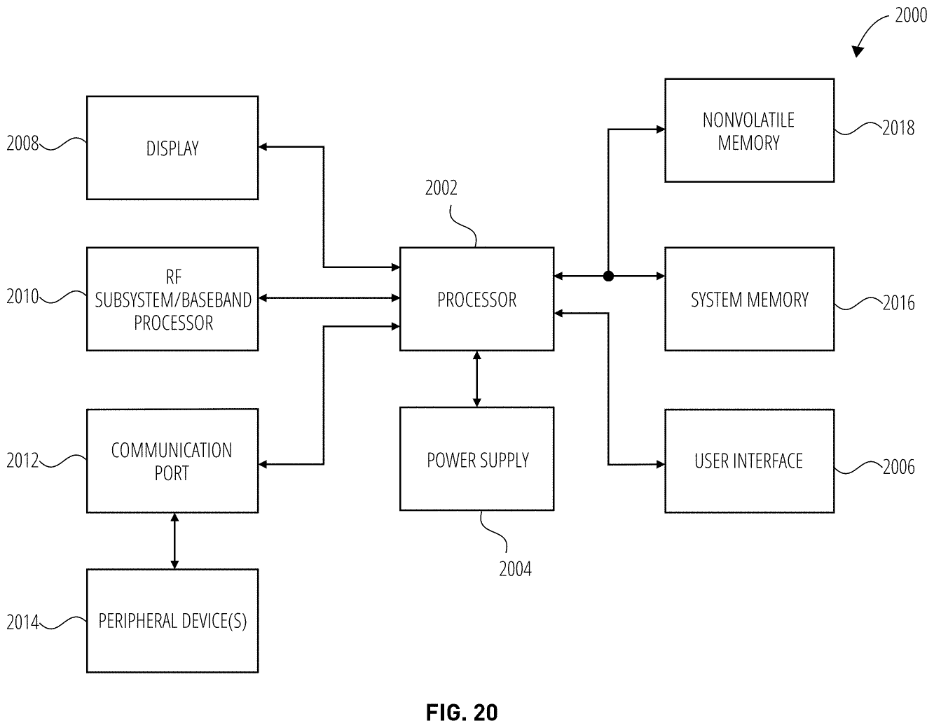

With reference to FIG. 20, shown is a block diagram of a processor-based system 2000. The processor-based system 2000 may include various microelectronic devices (e.g., the microelectronic device 1800 of FIG. 18) and microelectronic device structures (e.g., the microelectronic device structure 100 of FIG. 1) manufactured in accordance with embodiments of the present disclosure. The processor-based system 2000 may be any of a variety of types, such as a computer, a pager, a cellular phone, a personal organizer, a control circuit, or another electronic device. The processor-based system 2000 may include one or more processors 2002, such as a microprocessor, to control the processing of system functions and requests in the processor-based system 2000. The processor 2002 and other subcomponents of the processor-based system 2000 may include microelectronic devices (e.g., the microelectronic device 1800 of FIG. 18) and microelectronic device structures (e.g., the microelectronic device structure 100 of FIG. 1) manufactured in accordance with embodiments of the present disclosure.

The processor-based system 2000 may include a power supply 2004 in operable communication with the processor 2002. For example, if the processor-based system 2000 is a portable system, the power supply 2004 may include one or more of a fuel cell, a power scavenging device, permanent batteries, replaceable batteries, and/or rechargeable batteries. The power supply 2004 may also include an AC adapter; therefore, the processor-based system 2000 may be plugged into a wall outlet, for example. The power supply 2004 may also include a DC adapter such that the processor-based system 2000 may be plugged into a vehicle cigarette lighter or a vehicle power port, for example.

Various other devices may be coupled to the processor 2002 depending on the functions that the processor-based system 2000 performs. For example, a user interface 2006 may be coupled to the processor 2002. The user interface 2006 may include one or more input devices, such as buttons, switches, a keyboard, a light pen, a mouse, a digitizer and stylus, a touch screen, a voice recognition system, a microphone, or a combination thereof. A display 2008 may also be coupled to the processor 2002. The display 2008 may include an LCD display, an SED display, a CRT display, a DLP display, a plasma display, an OLED display, an LED display, a three-dimensional projection, an audio display, or a combination thereof. Furthermore, an RF subsystem/baseband processor 2010 may also be coupled to the processor 2002. The RF subsystem/baseband processor 2010 may include an antenna that is coupled to an RF receiver and to an RF transmitter. A communication port 2012, or more than one communication port 2012, may also be coupled to the processor 2002. The communication port 2012 may be adapted to be coupled to one or more peripheral devices 2014 (e.g., a modem, a printer, a computer, a scanner, a camera) and/or to a network (e.g., a local area network (LAN), a remote area network, an intranet, or the Internet).

The processor 2002 may control the processor-based system 2000 by implementing software programs stored in the memory (e.g., system memory 2016). The software programs may include an operating system, database software, drafting software, word processing software, media editing software, and/or media-playing software, for example. The memory (e.g., the system memory 2016) is operably coupled to the processor 2002 to store and facilitate execution of various programs. For example, the processor 2002 may be coupled to system memory 2016, which may include one or more of spin torque transfer magnetic random access memory (STT-MRAM), magnetic random access memory (MRAM), dynamic random access memory (DRAM), static random access memory (SRAM), racetrack memory, and/or other known memory types. The system memory 2016 may include volatile memory, nonvolatile memory, or a combination thereof. The system memory 2016 is typically large so it can store dynamically loaded applications and data. In some embodiments, the system memory 2016 may include semiconductor devices (e.g., the microelectronic device 1800 of FIG. 18) and structures (e.g., the microelectronic device structure 100 of FIG. 1), described above, or a combination thereof.

The processor 2002 may also be coupled to nonvolatile memory 2018, which is not to suggest that system memory 2016 is necessarily volatile. The nonvolatile memory 2018 may include one or more of STT-MRAM, MRAM, read-only memory (ROM) (e.g., EPROM, resistive read-only memory (RROM)), and Flash memory to be used in conjunction with the system memory 2016. The size of the nonvolatile memory 2018 is typically selected to be just large enough to store any necessary operating system, application programs, and fixed data. Additionally, the nonvolatile memory 2018 may include a high-capacity memory (e.g., disk drive memory, such as a hybrid-drive including resistive memory or other types of nonvolatile solid-state memory, for example). The nonvolatile memory 2018 may include microelectronic devices (e.g., the microelectronic device 1800 of FIG. 18) and structures (e.g., the microelectronic device structure 100 of FIG. 1) described above, or a combination thereof.

While the disclosed structures, apparatus (e.g., devices), systems, and methods are susceptible to various modifications and alternative forms in implementation thereof, specific embodiments have been shown by way of example in the drawings and have been described in detail herein. However, the disclosure is not intended to be limited to the particular forms disclosed. Rather, the disclosure encompasses all modifications, combinations, equivalents, variations, and alternatives falling within the scope of the disclosure as defined by the following appended claims and their legal equivalents.

What is claimed is:

1. A microelectronic device, comprising:
a stack structure comprising a vertically alternating sequence of insulative structures and conductive structures arranged in tiers, the tiers arranged in decks;
at least one live pillar extending through the decks of the stack structure to a source/drain region below the stack structure, the at least one live pillar comprising a channel material;
at least one source/drain contact extending through the decks of the stack structure; and
in a transition area horizontally between the at least one live pillar and the at least one source/drain contact, at least one dummy pillar extending through at least one of the decks of the stack structure, the at least one dummy pillar separated from the source/drain region by at least one of the tiers of a lower deck of the decks, the at least one dummy pillar spaced from the at least one source/drain contact.

2. The microelectronic device of claim 1, wherein the at least one source/drain contact defines a bow providing a maximum horizontal extension of the at least one source/drain contact.

3. The microelectronic device of claim 2, the at least one dummy pillar is spaced from the at least one source/drain contact by at least a minimum horizontal distance of at least twenty-five nanometers, the minimum horizontal distance defined at a vertical elevation of the bow.

4. The microelectronic device of claim 1, wherein the at least one live pillar and the at least one dummy pillar both comprise the channel material and at least one cell material.

5. The microelectronic device of claim 4, wherein, in the at least one dummy pillar, the at least one cell material horizontally surrounds and vertically underlays the channel material.

6. The microelectronic device of claim 4, wherein, in the at least one dummy pillar, the channel material extends through the at least one cell material.

7. The microelectronic device of claim 6, wherein, in the at least one dummy pillar, the channel material extends to an elevation below a lowest elevation of the at least one cell material.

8. The microelectronic device of claim 1, wherein the at least one dummy pillar extends only through an uppermost deck of the decks.

9. The microelectronic device of claim 1, wherein the at least one dummy pillar extends partially into a lowermost deck of the decks.

10. A method of forming a microelectronic device, the method comprising:
forming a tiered stack structure on a base structure, the tiered stack structure comprising a vertically alternating sequence of insulative structures and other structures arranged in tiers;
in a pillar array area of the tiered stack structure, forming live pillars comprising a channel material extending through an entire vertical height of the tiered stack structure to a source/drain region of the base structure;
in an additional area horizontally spaced from the pillar array area, forming at least one source/drain contact extending through the entire vertical height of the tiered stack structure;
in a transition area horizontally between the pillar array area and the additional area, forming dummy pillars comprising the channel material extending through a portion of the entire vertical height of the tiered stack structure; and
forming conductive plugs in electrical communication with the live pillars.

11. The method of claim 10, wherein forming the tiered stack, forming the live pillars, and forming the dummy pillars comprise:
forming a first deck of the tiered stack on the base structure, the first deck comprising a first portion of the vertically alternating sequence of the insulative structures and the other structures; and
in the pillar array area and not in the transition area, forming first openings extending through the first deck to the base structure.

12. The method of claim 11, wherein forming the tiered stack, forming the live pillars, and forming the dummy pillars further comprise:
forming a second deck of the tiered stack on the first deck, the second deck comprising a second portion of the vertically alternating sequence of the insulative structures and the other structures; and
in both the pillar array area and the transition area, forming second openings extending through the second deck.

13. The method of claim 12, wherein forming the live pillars and forming the dummy pillars further comprises:
forming at least one cell material in the first openings and in the second openings;
in the pillar array area, removing a portion of the at least one cell material to expose a portion of the base structure; and
forming the channel material on the at least one cell material in the first openings and in the second openings.

14. The method of claim 13, further comprising, before forming the channel material in the second openings, removing a portion of the at least one cell material in the transition area.

15. The method of claim 14, further comprising, after removing the portion of the at least one cell material and before forming the channel material in the second openings, extending the second openings to a vertical elevation below the at least one cell material.

16. The method of claim 10, further comprising forming at least one slit through the tiered stack structure in the pillar array area to define blocks, each of the blocks comprising some of the live pillars.

17. The method of claim 16, further comprising:
forming the other structures to comprise nonconductive material; and
at least partially replacing the other structures with conductive structures.

18. The method of claim 16, wherein forming the dummy pillars precedes forming the at least one source/drain contact.

19. A microelectronic device, comprising:
a stack structure comprising insulative structures vertically interleaved with conductive structures and arranged in tiers;
blocks of live pillar arrays comprising live pillars extending through the stack structure to a source/drain region below the stack structure;
at least one source/drain contact horizontally spaced from the blocks of the live pillar arrays, the at least one source/drain contact extending through the stack structure to at least one conductive landing structure proximate the source/drain region; and
at least one dummy pillar in at least one transition area horizontally between the at least one source/drain contact and the blocks of the live pillar arrays, the at least one dummy pillar spaced from the at least one source/drain contact and having a lower end vertically above the at least one conductive landing structure.

20. The microelectronic device of claim 19:
wherein the at least one source/drain contact comprises multiple source/drain contacts; and
further comprising at least one additional dummy pillar horizontally between neighboring source/drain contacts of the multiple source/drain contacts.

21. The microelectronic device of claim 19, wherein:
the at least one dummy pillar comprises multiple dummy pillars;
the at least one source/drain contact is horizontally surrounded by the multiple dummy pillars; and
each of the multiple dummy pillars is spaced from the at least one source/drain contact by at least a minimum separation distance.

22. The microelectronic device of claim 19, wherein the live pillars and the at least one dummy pillar each comprise:
a channel material; and
at least one cell material around the channel material in at least upper elevations of the stack structure.

23. The microelectronic device of claim 22, wherein the live pillars and the at least one dummy pillar each further comprise an insulative material horizontally surrounded by the channel material in at least the upper elevations of the stack structure.

24. The microelectronic device of claim 22, wherein the channel material of the at least one dummy pillar is in physical contact with conductive material of at least one of the conductive structures.

25. An electronic system, comprising:
a three-dimensional memory device comprising:
a stack structure comprising conductive structures vertically alternating with insulative structures and arranged in tiers;
at least one array of live pillars extending through the stack structure to a source/drain region below the stack structure; and
dummy pillars extending through a portion of the stack structure in at least one transition area horizontally between the at least one array of live pillars and at least one source/drain contact extending through the stack structure, the dummy pillars horizontally spaced from the at least one source/drain contact and vertically spaced from the source/drain region;
at least one processor in operable communication with the three-dimensional memory device; and
at least one peripheral device in operable communication with the at least one processor.
